(19) United States
(12) Patent Application Publication
(10) Pub. No.: US 2026/0277039 A1
(43) Pub. Date: Sep. 17, 2026

(54) Array Substrate, View Angle Control Cell and Display Apparatus

(71) Applicants: BOE TECHNOLOGY GROUP CO., LTD., Chaoyang District, Beijing (CN); HEFEI BOE OPTOELECTRONICS TECHNOLOGY CO., LTD., Hefei, Anhui (CN)

(72) Inventors: Dong Wang, Beijing (CN); Hongmin Li, Beijing (CN); Yijun Wang, Beijing (CN)

(21) Appl. No.: 18/996,431

(22) PCT Filed: May 4, 2023
(86) PCT No.: PCT/CN2023/092058

§ 371 Date: Jan. 17, 2025

(51) Int. Cl. G02F 1/13; G02F 1/1362; G02F 1/1368; H10D 86/40; H10D 86/60

(52) U.S. Cl. CPC G02F 1/1323; G02F 1/13629; G02F 1/1368; H10D 86/441; H10D 86/60

(57) ABSTRACT

An array substrate includes a substrate, a first wiring layer, a second wiring layer, a first electrode layer and a second electrode layer. The first wiring layer includes gate lines arranged at intervals in a first direction, and at least one gate line extends in a second direction intersecting with the first direction. The second wiring layer includes data lines arranged at intervals in the second direction, and at least one data line extends in the first direction. Two adjacent gate lines and two adjacent data lines define a dimming region configured to switch between a sharing state and a privacy protection state. The first electrode layer includes a first electrode located in the dimming region. The second electrode layer includes a second electrode of which an orthographic projection on the substrate is at least partially non-overlapping with an orthographic projection of the first electrode on the substrate.

### CROSS-REFERENCE TO RELATED APPLICATION

This application is the United States national phase of International Patent Application No. PCT/CN2023/092058, filed May 4, 2023, the disclosure of which is hereby incorporated by reference in its entirety.

### BACKGROUND OF THE INVENTION

### Field of the Invention

The present disclosure relates to the field of display technologies, and in particular, to an array substrate, a view angle control cell and a display apparatus.

### Description of Related Art

With the development of display technologies, people have higher confidentiality and privacy requirements on display apparatuses; in order to prevent “information leakage” due to “visual intrusion” when working in public places, a display apparatus with a privacy protection function is developed. The privacy protection function means that the display apparatus has two display states: a sharing state and a privacy protection state. In existing privacy protection display technologies, the entire screen of the display apparatus is generally processed to achieve privacy protection; that is, the entire display area of the display apparatus displays an image in the sharing state or in the privacy protection state. However, as the size of the display apparatus increases, the above display technology that can only achieve privacy protection in an entire area can no longer meet the requirements of users.

### SUMMARY OF THE INVENTION

In an aspect, an array substrate is provided. The array substrate includes a substrate, a first wiring layer, a second wiring layer, a first electrode layer and a second electrode layer. The first wiring layer includes a plurality of gate lines arranged at intervals in a first direction, and at least one gate line extends in a second direction. The first direction intersects with the second direction. The second wiring layer is disposed on a side of the first wiring layer away from the substrate and includes a plurality of data lines arranged at intervals in the second direction, and at least one data line extends in the first direction. An orthographic projection of a gate line of the plurality of gate lines on the substrate intersects with an orthographic projection of a data line of the plurality of data lines on the substrate, two adjacent gate lines of the plurality of gate lines and two adjacent data lines of the plurality of data lines define a dimming region, and the dimming region is configured to switch between a sharing state and a privacy protection state. The first electrode layer is disposed on a side of the second wiring layer away from the substrate, the first electrode layer includes a plurality of first electrodes, and a first electrode is at least partially located in the dimming region. The second electrode layer is disposed on a side of the first electrode layer away from the substrate, and the second electrode layer includes a second electrode. An orthographic projection of the second electrode on the substrate is at least partially non-overlapping with an orthographic projection of the first electrode on the substrate.

In some embodiments, the dimming region is provided with a thin film transistor therein; the thin film transistor is electrically connected to a gate line of the two adjacent gate lines, a data line of the two adjacent data lines and the first electrode, and configured to transmit a data signal from the data line to the first electrode under control of a scanning signal from the gate line. The second electrode include a plurality of avoidance openings, and the dimming region is provided with an avoidance opening therein; an orthographic projection of the avoidance opening on the substrate at least partially overlaps with an orthographic projection of the thin film transistor on the substrate.

In some embodiments, the thin film transistor includes a gate pattern, a semiconductor pattern, a source pattern and a drain pattern. The gate pattern is disposed in the first wiring layer and connected to the gate line. The semiconductor pattern is disposed between the first wiring layer and the second wiring layer. The source pattern is disposed in the second wiring layer and connected to the data line. The drain pattern is disposed in the second wiring layer and spaced apart from the source pattern, and an orthographic projection of the drain pattern on the substrate is non-overlapping with the orthographic projection of the first electrode on the substrate. An orthographic projection of the gate pattern on the substrate covers orthographic projections of the semiconductor pattern and the source pattern on the substrate, and partially overlaps with the orthographic projection of the drain pattern on the substrate; the orthographic projection of the avoidance opening on the substrate partially overlaps with the orthographic projections of the gate pattern, the semiconductor pattern, and the source pattern on the substrate, and covers the orthographic projection of the drain pattern on the substrate.

In some embodiments, the avoidance opening includes a first opening portion. A shape of a border of the first opening portion is substantially same as a shape of a border of the semiconductor pattern, and an orthographic projection of the first opening portion on the substrate is located within the orthographic projection of the semiconductor pattern on the substrate.

In some embodiments, the second electrode layer further includes a transfer block. The transfer block is located in the avoidance opening and having a spacing from a border of the avoidance opening. The transfer block is electrically connected to both the drain pattern and the first electrode.

In some embodiments, the avoidance opening includes a second opening portion. A shape of a border of the second opening portion is substantially same as a shape of a border of the transfer block, and the border of the second opening portion surrounds the transfer block.

In some embodiments, a spacing between the border of the transfer block and the border of the second opening portion is in a range of 6 μm to 20 μm, inclusive.

In some embodiments, an orthographic projection of the transfer block on the substrate is non-overlapping with orthographic projections of the data line and the gate line on the substrate.

In some embodiments, the second electrode includes a plurality of third electrode strips and fourth electrode strips. The plurality of third electrode strips are arrange at intervals in the second direction and extend in the first direction. The fourth electrode strips are connected to ends of the plurality of third electrode strips, an extension direction of a fourth electrode strip is parallel to an extension direction of the gate line, and an orthographic projection of the fourth electrode strip on the substrate at least partially overlaps with the orthographic projection of the gate line on the substrate.

In some embodiments, the fourth electrode strip includes at least one protruding portion and straight portions connected to the protruding portion; in the first direction, a dimension of a protruding portion of the at least one protruding portion is greater than a dimension of a straight portion of the straight portions; in the second direction, and a dimension of the protruding portion is greater than a dimension of the straight portion.

In some embodiments, the fourth electrode strip includes a plurality of protruding portions and a plurality of straight portions connected to the plurality of protruding portions, and multiple third electrode strips located in a same dimming region include a first electrode sub-strip, s second electrode sub-strip and s third electrode sub-strip. Two ends of the first electrode sub-strip in the first direction are connected to straight portions. In the first direction, an end of the second electrode sub-strip is connected to a straight portion, and another end of the second electrode sub-strip is connected to a protruding portion. Two ends of the third electrode sub-strip in the first direction are connected to protruding portions.

In some embodiments, the second electrode further includes a first slit located between two adjacent third electrode strips. The first electrode includes a plurality of first electrode strips arranged at intervals in the second direction and a second slit located between two adjacent first electrode strips. Orthographic projections of the first slit and the second slit on the substrate partially overlap, and an overlapping portion of the first slit and the second slit defines a third slit; a dimension of the third slit in the second direction is less than a dimension of a first electrode strip of the two adjacent first electrode strips in the second direction, and/or less than a dimension of a third electrode strip of the two adjacent third electrode strips in the second direction.

In some embodiments, two adjacent first slits in the first direction are a first sub-slit and a second sub-slit, respectively. The first sub-slit and the second sub-slit are respectively located on two sides of a fourth electrode strip and connected to two opposite edges of the fourth electrode strip. An end of the first sub-slit proximate to the fourth electrode strip is connected to a protruding portion, and an end of the second sub-slit proximate to the fourth electrode strip is connected to a flat-straight portion. A dimension of the first sub-slit in the first direction is less than a dimension of the second sub-slit in the first direction.

In some embodiments, in a same dimming region, multiple first slits include a third sub-slit, a fourth sub-slit and a fifth sub-slit. Two ends of the third sub-slit in the first direction are connected to straight portions. In the first direction, an end of the fourth sub-slit is connected to a straight portion, and another end of the fourth sub-slit is connected to a protruding portion. Two ends of the fifth sub-slit in the first direction are connected to protruding portions. A dimension of the third sub-slit in the first direction is greater than a dimension of the fourth sub-slit in the first direction, and the dimension of the fourth sub-slit in the first direction is greater than a dimension of the fifth sub-slit in the first direction.

In some embodiments, the first electrode includes a plurality of first electrode strips arranged at intervals in the second direction, and the second electrode includes a plurality of third electrode strips arranged at intervals in the second direction. Orthographic projections of the plurality of first electrode strips and the plurality of third electrode strips on the substrate are alternately arranged in the second direction, a first electrode strip and an adjacent third electrode strip is provided with a fourth slit therebetween, and a dimension of the fourth slit in the second direction is less than a dimension of the first electrode strip in the second direction, and/or less than a dimension of the third electrode strip in the second direction.

In some embodiments, in the dimming region, the first electrode includes a plurality of first electrode strips arranged at intervals in the second direction and a second electrode strip of which both ends are connected to each other. The plurality of first electrode strips extend in the first direction. The second electrode strip is connected to two ends of a first electrode strip of the plurality of first electrode strips in the first direction to form a structure in which the second electrode strip encloses the plurality of first electrode strips.

In some embodiments, the second electrode strip includes two fourth electrode sub-strips and two fifth electrode sub-strips. The two fourth electrode sub-strips are oppositely arranged in the first direction. An extension direction of a fourth electrode sub-strip is parallel to an extension direction of the gate line. The two fifth electrode sub-strips are oppositely arranged in the second direction. An extension direction of a fifth electrode sub-strip is parallel to an extension direction of the data line. A spacing between orthographic projections of the fourth electrode sub-strip and the gate line on the substrate is equal to a spacing between orthographic projections of the fifth electrode sub-strip and the data line on the substrate.

In some embodiments, the fourth electrode sub-strip has a zigzag structure, or the fourth electrode sub-strip has a concave-convex structure.

In some embodiments, a first recess is provided at an edge of the fourth electrode sub-strip proximate to the gate line, and an orthographic projection of the first recess on the substrate and an orthographic projection of the gate line on the substrate have a spacing therebetween.

In some embodiments, the gate line includes at least one light adjustment portion and a connection portion connected to the light adjustment portion, and a width of a light adjustment portion is greater than a width of the connection portion.

In some embodiments, a ratio of a maximum width of the light adjustment portion to the width of the connection portion is in a range of 1.5 to 4, inclusive.

In some embodiments, a ratio of a length of the connection portion to a length of the light adjustment portion is in a range of 1.5 to 3, inclusive.

In some embodiments, an orthographic projection of the light adjustment portion on the substrate is in a shape of a hexagon or an octagon.

In some embodiments, the gate line is routed along a broken line and includes a plurality of extension sections sequentially connected in the second direction. An extension section includes a plurality of light adjustment portions and a plurality of connection portions that are alternately connected in sequence; and two ends of the extension section are connection portions.

In some embodiments, a second recess is provided on a side of the first electrode proximate to the light adjustment portion; a shape of the second recess is same as a shape of the light adjustment portion on a side proximate to the first electrode, and a spacing between the second recess and the light adjustment portion is equal to a spacing between the first electrode and the connection portion.

In some embodiments, an orthographic projection of the light adjustment portion on the substrate is non-overlapping with an orthographic projection of a thin film transistor on the substrate.

In some embodiments, the gate line includes a plurality of extension sections, and the plurality of extension sections include a plurality of first extension sections and a plurality of second extension sections that are alternately connected; a first extension section and a second extension section that are connected to each other are symmetrically arranged about a first reference line, and an included angle between an extension direction of the first extension section and the second direction or between an extension direction of the second extension direction and the second direction is in a range of 53° to 73°, inclusive; the first reference line is parallel to the first direction.

In some embodiments, the data line is routed along a broken line and includes a plurality of third extension sections and a plurality of fourth extension sections that are alternately arranged and connected in the first direction; a third extension section and a fourth extension section that are connected to each other are symmetrically arranged about a second reference line, and an included angle between an extension direction of the third extension section and the first direction or between an extension direction of the fourth extension direction and the first direction is in a range of 5° to 10°, inclusive; the second reference line is parallel to the second direction.

In some embodiments, the second wiring layer further includes a plurality of common voltage signal lines arranged at intervals in the first direction. In the second direction, the plurality of data lines and the plurality of common voltage signal lines are alternately arranged, and a data line and an adjacent common voltage signal line are symmetrically arranged.

In some embodiments, a common voltage signal line of the plurality of common voltage signal lines includes a widened portion, the widened portion is electrically connected to the second electrode, and an orthographic projection of the widened portion on the substrate is located in the orthographic projection of the gate line on the substrate.

In some embodiments, the array substrate includes a display area and a peripheral area surrounding the display area. The array substrate further includes a common voltage signal bus line, a gate driving circuit, a fan-out trace, a chip on film and a driver chip. The common voltage signal bus line is located in the peripheral area and surrounding the display area, and in a case where the array substrate includes a common voltage signal line, an end of the common voltage signal line in the first direction is connected to the common voltage signal bus line. The gate driving circuit is located in the peripheral area and disposed on at least one side of the display area in the second direction, and is electrically connected to the gate line. The fan-out trace is located in the peripheral area and disposed on a side of the display area in the first direction, and is electrically connected to the data line. The chip on film is connected to the fan-out trace. The driver chip is bonded to the chip on film.

In another aspect, a view angle control cell is provided, which includes the array substrate according to any one of the above embodiments, an opposite substrate and a liquid crystal layer. The opposite substrate is arranged opposite to the array substrate, and the opposite substrate and the array substrate define a liquid crystal cell. The liquid crystal layer is located in the liquid crystal cell, and configured to, under control of the array substrate, adjust deflection directions of liquid crystal molecules in the liquid crystal layer and located in each dimming region to control light entering each dimming region to be emitted from the liquid crystal layer in the privacy protection state or the sharing state.

In some embodiments, the view angle control cell further includes a plurality of spacers. The plurality of spacers are located in the liquid crystal cell and configured to support the array substrate and the opposite substrate. Each spacer includes an end surface in contact with the array substrate, and an orthographic projection of the end surface on the substrate is located within an orthographic projection of a light adjustment portion on the substrate.

In yet another aspect, a display apparatus is provided. The display apparatus includes the view angle control cell according to any one of the above embodiments, a backlight module and a liquid crystal display panel. The backlight module is disposed on a side of the view angle control cell proximate to the array substrate and configured to output light, whose propagation direction is perpendicular to the view angle control cell, toward a direction approaching the view angel control cell. The liquid crystal display panel is disposed on a side of the view angel control cell away from the backlight module.

In some embodiments, the liquid crystal display panel includes a plurality of sub-pixels, a dimension of a sub-pixel in the first direction is denoted as D1, and a dimension of the sub-pixel in the second direction is denoted as D2. The array substrate includes a plurality of dimming regions, a dimension of a dimming region in the first direction is denoted as D3, and a dimension of the dimming region in the second direction is denoted as D4; D3=N×D1+M; D4=O×D2+P; 2≤N≤8, and N is a positive integer; 0.1 μm≤M≤0.8 μm; 2≤O≤8, and O is a positive integer; 0.1 μm≤P≤0.8 μm.

### BRIEF DESCRIPTION OF THE DRAWINGS

In order to describe the technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a liquid crystal display panel, in accordance with some embodiments;

FIG. 3A is a structural diagram of a view angle control cell in a transparent state, in accordance with some embodiments;

FIG. 3B is a structural diagram of a view angle control cell in a scattering state, in accordance with some embodiments;

FIG. 4 is a structural diagram of an array substrate, in accordance with some embodiments;

FIG. 5 is a structural diagram of a first wiring layer, in accordance with some embodiments;

FIG. 6 is a partial enlarged view of the region A1 in FIG. 5;

FIG. 7 is a structural diagram of a second wiring layer, in accordance with some embodiments;

FIG. 8A is a structural diagram of a dimming region, in accordance with some embodiments;

FIG. 8B is a structural diagram of a dimming region, in accordance with some other embodiments;

FIG. 9A is a diagram showing a positional relationship between a first electrode and a dimming region, in accordance with some embodiments;

FIG. 9B is a partial enlarged view of the region A2 in FIG. 9A;

FIG. 10 is a structural diagram of a first electrode, in accordance with some embodiments;

FIG. 11 is a partial enlarged view of the region B1 in FIG. 9B excluding a second electrode;

FIG. 12 is a partial enlarged view of the region B2 in FIG. 9B excluding a second electrode;

FIG. 13A is a partial enlarged view of the region B3 in FIG. 9B excluding a second electrode;

FIG. 13B is a partial enlarged view of the region B3 in FIG. 9B;

FIG. 14 is a structural diagram of a thin film transistor, in accordance with some embodiments;

FIG. 15 is a sectional view taken along the section line C1-C1 in FIG. 13B;

FIG. 16A is a structural diagram of a second electrode layer, in accordance with some embodiments;

FIG. 16B is a partial enlarged view of the region A3 in FIG. 16A;

FIG. 17A is a partial enlarged view of the region B1 in FIG. 9B;

FIG. 17B is a sectional view taken along the section line C2-C2 in FIG. 17A;

FIG. 18 is a partial enlarged view of the region B4 in FIG. 9B;

FIG. 19 is a sectional view taken along the section line C3-C3 in FIG. 18;

FIG. 20 is a partial enlarged view of the region B2 in FIG. 9B;

FIG. 21 is a sectional view taken along the section line C4-C4 in FIG. 20;

FIG. 22 is a partial enlarged view of the region B5 in FIG. 9B;

FIG. 23 is a sectional view taken along the section line C5-C5 in FIG. 22;

FIG. 24 is a structural diagram of a display apparatus performing privacy protection display in a partition manner, in accordance with some embodiments;

FIG. 25 is a structural diagram of dimming regions and a display panel, in accordance with some embodiments; and

FIG. 26 is a plan view of an array substrate, in accordance with some embodiments.

### DESCRIPTION OF THE INVENTION

The technical solutions in some embodiments of the present disclosure will be clearly and completely described below in conjunction with the accompanying drawings. Obviously, the embodiments to be described are merely some rather than all embodiments of the present disclosure. All other embodiments obtained by a person of ordinary skill in the art based on the embodiments provided by the present disclosure should belong to the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “including, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the term such as “first” or “second” is used for descriptive purposes only, but not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the terms “coupled”, “connected” and derivatives thereof may be used. The term “connected” should be understood in a broad sense; for example, the term “connected” may represent a fixed connection, a detachable connection, or a one-piece connection; alternatively, it may represent a direct connection or an indirect connection through an intermediate medium. The term “coupled” indicates, for example, that two or more components are in direct physical or electrical contact with each other. However, the term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value; the acceptable range of deviation may be determined, for example, by a person of ordinary skill in the art, considering measurement in question and errors (i.e., limitations of a measurement system) associated with measurement of a particular quantity.

The term such as “parallel”, “perpendicular” or “equal” as used herein includes a stated condition and a condition similar to the stated condition within an acceptable range of deviation; the acceptable range of deviation may be determined, for example, by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, in a case where a layer or element is referred to as being on another layer or substrate, it may be that the layer or element is directly on the another layer or substrate, or it may be that there is an intermediate layer between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

Some embodiments of the present disclosure provide a display apparatus, and the display apparatus may be any apparatus that displays images whether in motion (e.g., a video) or stationary (e.g., static images) and whether textual or graphical. For example, the display apparatus may be any product or component having a display function, such as a television, a notebook computer, a tablet computer, a mobile phone, a personal digital assistant (PDA), a navigator, a wearable device, an augmented reality (AR) device, or a virtual reality (VR) device.

The display apparatus may be a liquid crystal display (LCD) apparatus. The liquid crystal display apparatus may be in a vertical alignment (VA) display mode, a twisted nematic (TN) display mode, an advanced super dimension switch (ADS) display mode or an in-plane switching (IPS) display mode, which is not limited in the embodiments of the present disclosure.

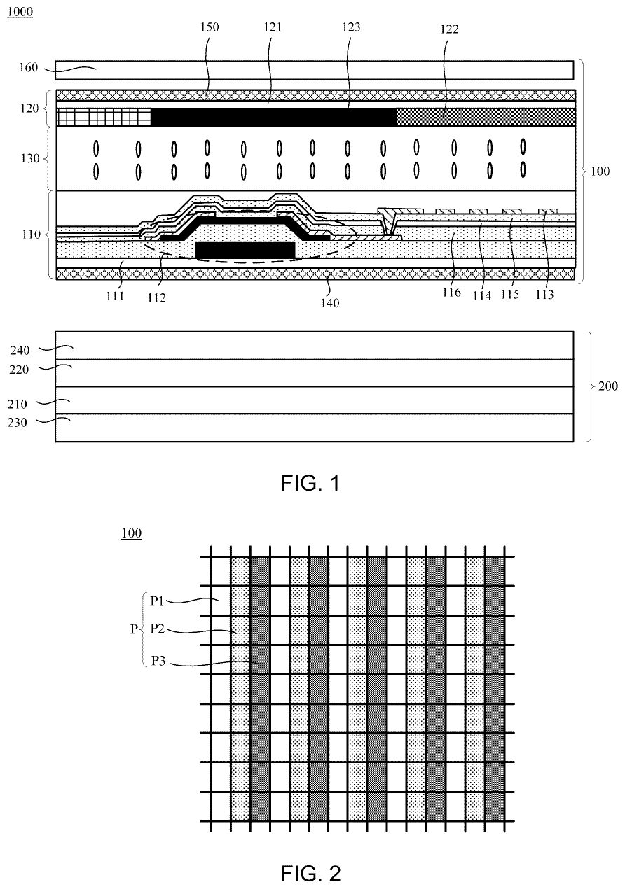

In a case where the display apparatus is a liquid crystal display apparatus, referring to FIG. 1, the display apparatus 1000 includes a liquid crystal display panel 100 and a backlight module 200. Generally, the liquid crystal display panel 100 includes a control substrate 110 (which may also be referred to as an array substrate) and a color filter substrate 120 that are arranged opposite each other. A second liquid crystal layer 130 is included between the control substrate 110 and the color filter substrate 120.

Referring to FIG. 2, the liquid crystal display panel 100 includes a plurality of sub-pixels P arranged in an array. The plurality of sub-pixels P may include, for example, first sub-pixels P1 for emitting light of a first color, second sub-pixels P2 for emitting light of a second color, and third sub-pixels P3 for emitting light of a third color. As an example, the first color, the second color and the third color are red, green and blue, respectively. In FIG. 2, each grid defines a sub-pixel P, and grid lines may be signal lines (e.g., scanning signal lines and data signal lines) of the liquid crystal display panel 100. The plurality of sub-pixels P are only illustrated arranged, and the plurality of sub-pixels P may also be arranged in other ways, which is not specifically limited in the embodiments of the present disclosure.

Each sub-pixel P includes a control circuit (not shown in the figures) located in the control substrate 110, and with continued reference to FIG. 1, the control circuit may include, for example, a thin film transistor 112 and a pixel electrode 113 that are located on a first base substrate 111. The thin film transistor 112 includes an active layer, a source, a drain, a gate and a gate insulating layer. The source and the drain are both in contact with the active layer, and the pixel electrode 113 is electrically connected to the drain of the thin film transistor 112.

In some embodiments, as shown in FIG. 1, the control substrate 110 further includes a common electrode 114 disposed on the first base substrate 111. The pixel electrode 113 and the common electrode 114 may be disposed in different layers. In this case, as shown in FIG. 1, a first insulating layer 115 is provided between the pixel electrode 113 and the common electrode 114, and a second insulating layer 116 is provided between the common electrode 114 and the thin film transistor 112.

In the case where the common electrode 114 is disposed between the thin film transistor 112 and the pixel electrode 113, as shown in FIG. 1, the color filter substrate 120 includes a color filter layer 122 disposed on a second base substrate 121. The color filter layer 122 includes at least red color resist units, green color resist units and blue color resist units. The red color resist units, green color resist units and blue color resist units directly face the sub-pixels of the liquid crystal display panel 100 in a one-to-one correspondence. The color filter substrate 120 further includes a black matrix pattern 123 disposed on the second base substrate 121, and the black matrix pattern 123 is used to separate the red color resist units, the green color resist units and the blue color resist units from each other.

In some other embodiments, the pixel electrode 113 and the common electrode 114 may be disposed in a same layer. In this case, the pixel electrode 113 and the common electrode 114 are both of a comb-tooth structure (not shown in the figures) including a plurality of stripe-shaped sub-electrodes; alternatively, the common electrode 114 may be disposed in the color filter substrate 120 (not shown in the figures), which is not specifically limited in the embodiments of the present disclosure.

In some embodiments, as shown in FIG. 1, the control substrate 110 is provided with a first polarizer 140 on a side away from the second liquid crystal layer 130, and the color filter substrate 120 is provided with a second polarizer 150 on a side away from the second liquid crystal layer 130. The polarization directions of the first polarizer 140 and the second polarizer 150 are perpendicular to each other. The liquid crystal display panel 100 may further include a protective cover 160 disposed on a side of the color filter substrate 120 away from the control substrate 110.

It will be understood that, the liquid crystal display panel 100 may further include other structures, which will not be enumerated in the embodiments of the present disclosure. For example, the liquid crystal display panel 100 may further include a third alignment film (not shown in the figures) disposed on a side of the control substrate 110 proximate to the second liquid crystal layer 130, a fourth alignment film (not shown in the figures) disposed on a side of the color filter substrate 120 proximate to the second liquid crystal layer 130, etc.

The backlight module 200 is disposed on a non-display side of the liquid crystal display panel 100 and used for providing a planar light source for the liquid crystal display panel 100. The backlight module 200 may be an edge-lit backlight module or a back-lit backlight module. In the embodiments of the present disclosure, as shown in FIG. 1, description is made by taking an example in which the backlight module 200 is a back-lit backlight module. In the case where the backlight module 200 is the back-lit backlight module, as shown in FIG. 1, the backlight module 200 may include a backlight source 210, a light guide plate 220 and a reflective sheet 230. The backlight source 210 is disposed on a side of the light guide plate 220 away from the liquid crystal display panel 100 and may include a plurality of point light sources (e.g., LED beads) arranged in an array. The light guide plate 220 is used to homogenize the light emitted by the backlight source 210. The reflective sheet 230 is disposed on a side of the backlight source 210 away from the liquid crystal display panel 100 and used to reflect the light emitted by the backlight source 210 and directed toward the reflective sheet 230, which increases the amount of light emitted from the backlight module 200 and directed toward the liquid crystal display panel 100, thereby improving the luminous efficiency of the display apparatus.

In some embodiments, as shown in FIG. 1, the backlight module 200 further includes an inverse prism 240 located on a side of the light guide plate 220 proximate to the liquid crystal display panel 100. The inverse prism 240 is used to refract at least part of the light emitted from the light guide plate 220 to enable the light to be emitted with a front viewing angle (causing the light to be emitted in a direction perpendicular to a surface of the light guide plate 220 proximate to the liquid crystal display panel 100), so as to improve the luminous efficiency of the backlight module 200. That is, the inverse prism 240 may have a certain collimation effect on the light emitted from the light guide plate 220.

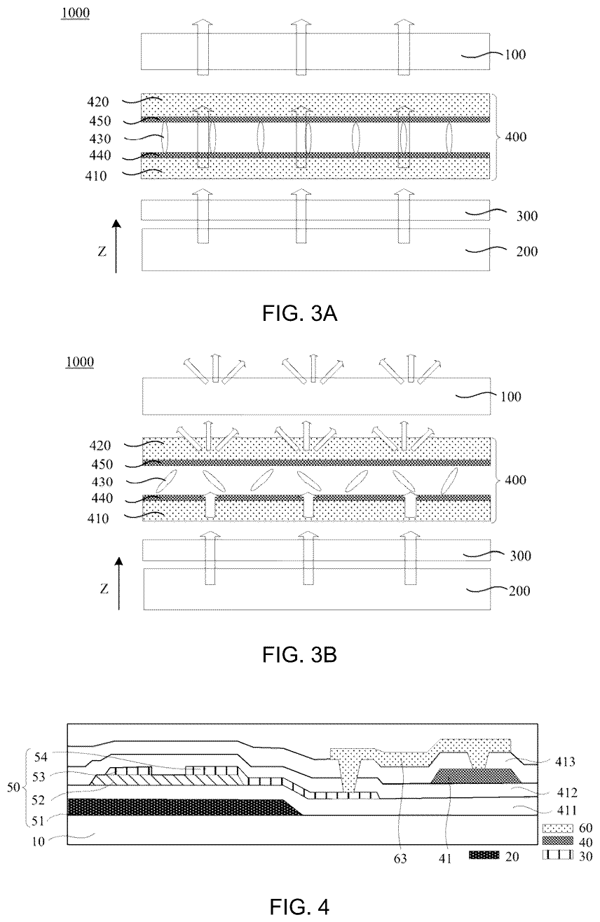

In some embodiments, the display apparatus 1000 may be a display apparatus 1000 with a privacy protection function. Referring to FIGS. 3A and 3B, the display apparatus 1000 further includes a collimating film 300 and a view angle control cell 400. The collimating film 300 and the view angle control cell 400 are both disposed between the liquid crystal display panel 100 and the backlight module 200, and the collimating film 300 is closer to the backlight module 200 than the view angle control cell 400; that is, the collimating film 300 is located between the view angle control cell 400 and the backlight module 200. In FIGS. 3A and 3B, the arrows indicate the propagation directions of the light emitted from the backlight module 200.

The collimating film 300 is used to further collimate the light emitted from the backlight module 200, so that the light emitted from the backlight module 200 and entering the collimating film 300 can be emitted in a direction perpendicular to a surface of the collimating film 300 proximate to liquid crystal display panel 100; that is, the collimating film 300 and the backlight module 200 cooperate to output light in a direction perpendicular to the liquid crystal display panel 100 toward the view angle control cell 400.

The view angle control cell 400 may also be referred to as a smart view control solution (SVC) cell, or a view angle dimming box. The view angle control cell 400 is configured to adjust the propagation direction of the light passing through the view angle control cell 400 to control the direction in which the light emitted from the liquid crystal display panel 100, so that the display apparatus 1000 may display images in a privacy protection display state (abbreviated as a privacy protection state) and/or a sharing display state (abbreviated as a sharing state).

For example, the view angle control cell 400 may operate in a transparent state and/or a scattering state. As shown in FIG. 3A, in the case where the view angle control cell 400 operates in the transparent state, long axis directions of liquid crystal molecules in a first liquid crystal layer 430 may, for example, be parallel to a third direction Z (a direction perpendicular to an array substrate 410), and the view angle control cell 400 does not change the propagation direction of the light passing through the view angle control cell 400. In this case, the light entering the view angle control cell 400 from the backlight module 200 passes through the view angle control cell 400 still in a direction perpendicular to the liquid crystal display panel 100, and then enters and passes through the liquid crystal display panel 100; the propagation direction of light on a display side of the liquid crystal display panel 100 is perpendicular to a light exit surface of the liquid crystal display panel 100, so that the content displayed on the liquid crystal display panel 100 may be seen only in a region facing the liquid crystal display panel 100 (the line of sight is perpendicular to the liquid crystal display panel 100), and the content displayed on the liquid crystal display panel 100 cannot be seen or cannot be clearly seen in a peripheral region (a surrounding region) of the liquid crystal display panel. In this way, the liquid crystal display panel 100 may be prevented from being viewed by surrounding people, which mean that the display apparatus 1000 displays images in the privacy protection state.

As shown in FIG. 3B, in the case where the view angle control cell 400 operates in the scattering state, the long axis directions of the liquid crystal molecules in the first liquid crystal layer 430 may, for example, have an angle with respect to the third direction Z (the direction perpendicular to the array substrate 410), and the view angle control cell 400 may change the propagation direction of the light passing through the view angle control cell 400, so that the light is emitted in a scattered state. Thus, the light emitted from the backlight module 200 and entering the view angle control cell 400 in the direction perpendicular to the view angle control cell 400 passes through the view angle control cell 400, and then enters and passes through the liquid crystal display panel 100 in a scattered state; the light on the display side of the liquid crystal display panel 100 diverges in every direction. In this case, the content displayed on the liquid crystal display panel 100 may be seen both in the region directly facing the liquid crystal display panel 100 and in the region surrounding the liquid crystal display panel 100, which means that the display apparatus 1000 displays images in the sharing state.

In some embodiments, referring to FIG. 3B, the view angle control cell 400 includes an array substrate 410, an opposite substrate 420 and a first liquid crystal layer 430. The array substrate 410 and the opposite substrate 420 are arranged opposite to each other, and a liquid crystal cell is provided between the array substrate 410 and the opposite substrate 420. The first liquid crystal layer 430 is located in the liquid crystal cell between the array substrate 410 and the opposite substrate 420.

In some embodiments, a liquid crystal dimming film may be adopted as the first liquid crystal layer 430; for example, polymer dispersed liquid crystals (PDLC) may be adopted. The polymer dispersed liquid crystals (mainly works in a transparent state or a scattering state) are a material obtained by mixing low molecule liquid crystals and a pre-polymer adhesive to undergo polymerization reaction to form micron-sized liquid crystal droplets evenly dispersed in the polymer network, and the material has the corresponding electro-optical characteristics from the dielectric anisotropy of liquid crystal molecules. It will be noted that, the material of the first liquid crystal layer 430 is not limited the above, as long as the liquid crystals can switch between the transparent state and the scattering state. For example, the liquid crystals in the first liquid crystal layer 430 may be smectic liquid crystals, but are not limited thereto.

For example, referring to FIG. 3B, the view angle control cell 400 may further include a first alignment film 440 disposed on a side of the array substrate 410 proximate to the first liquid crystal layer 430 and a second alignment film 450 disposed on a side of the opposite substrate 420 proximate to the first liquid crystal layer 430. The first alignment film 440 and the second alignment film 450 are used to control orientations of the liquid crystal molecules in the first liquid crystal layer 430; for example, the first alignment film 440 and the second alignment film 450 may be used to control the orientations of the liquid crystal molecules without being affected by an electric field, which may be understood as that the first alignment film 440 and the second alignment film 450 are used to limit pretilt angles of the liquid crystal molecules.

In some embodiments, referring to FIG. 4, the array substrate 410 includes a substrate 10, a first wiring layer 20, a second wiring layer 30, a first electrode layer 40, a plurality of thin film transistors 50 and a second electrode layer 60. The first wiring layer 20 is disposed on a side of the substrate 10, the second wiring layer 30 is disposed on a side of the first wiring layer 20 away from the substrate 10, the first electrode layer 40 is disposed on a side of the second wiring layer 30 away from the substrate 10, and the second electrode layer 60 is disposed on a side of the first electrode layer 40 away from the substrate 10. That is, the first wiring layer 20, the second wiring layer 30, the first electrode layer 40 and the second electrode layer 60 are sequentially arranged in a direction away from the substrate 10.

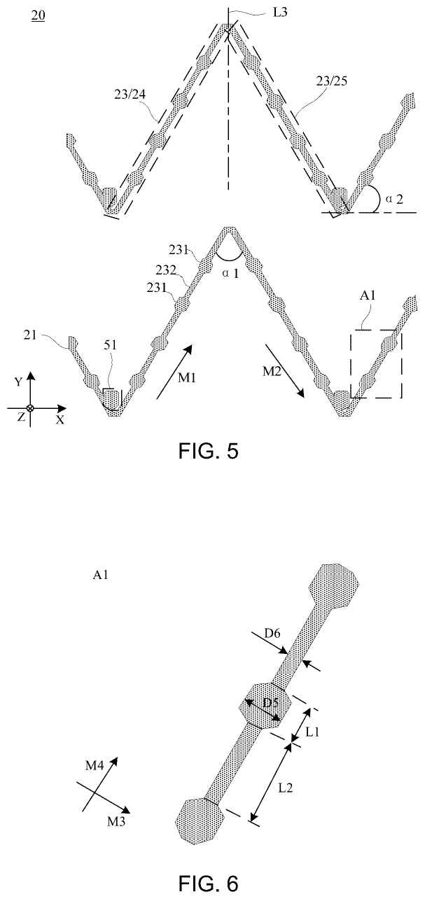

Referring to FIG. 5, the first wiring layer 20 includes a plurality of gate lines 21 arranged at intervals in a first direction Y. The gate line 21 extends in a second direction X as a whole. The first direction Y intersects with the second direction X; for example, the first direction Y and the second direction X are perpendicular to each other. The gate line 21 extending in the second direction X as a whole means that the gate line 21 extends in the second direction X on a macro level, but the gate line 21 may have a portion extending in a direction intersecting with the second direction X on a micro level; for example, the gate line 21 may be routed along a broken line. It will be understood that, the gate line 21 is configured to transmit a scanning signal.

In some embodiments, as shown in FIG. 5, the gate line 21 is routed along a broken line. The gate line 21 includes a plurality of extension sections 23 sequentially connected in the second direction X, and two extension sections 23 that are connected to each other have a first included angle α1 therebetween. The first included angle α1 may be in a range from 34° to 74°.

In the liquid crystal display apparatus 1000, in a case where two stacked layers each has a grid pattern and the grid patterns of the two layers are similar to each other, moiré pattern easily appears; that is, alternating light and dark stripes will be perceived by human eyes, which affects the visual experience. As shown in FIG. 2, in the liquid crystal display panel 100, projections of the plurality of sub-pixels P on the view angle control cell 400 are substantially in a shape of a rectangle. The gate line 21 is arranged to be routed along a broken line, there is an included angle between the extension direction of the gate line 21 and the grid defining the sub-pixel P; that is, there is an included angle between the extension direction of the gate line 21 and an extension direction of a signal line in the liquid crystal display panel 100. In this way, there is a difference between a grid formed by the gate lines 21 and the grid formed by the sub-pixels P in shape, which is conducive to reducing the probability of appearance of moire pattern of the display apparatus 1000.

In some embodiments, referring to FIG. 5, the plurality of extension sections 23 include first extension sections 24 and second extension sections 25 that are alternately arranged in the second direction X. A first extension section 24 and a second extension section 25 that are connected to each other are symmetrically arranged about a first reference line L3, and a second included angle α2 between an extension direction of the first extension section 24 and the second direction X or between the second extension section 25 and the second direction X is in a range of 53° to 73°. It has been verified that in a case where the second included angle α2 is in the above range, the risk of moiré pattern appearing in the display apparatus 1000 may be reduced to the greatest extent. The first reference line L3 is parallel to the first direction Y and passes through a corner where the first extension section 24 and the second extension section 25 are connected. The first extension section 24 is an extension section 23 extending in a first reference direction M1, and the second extension section 25 is an extension section 23 extending in a second reference direction M2. The first extension section 24 and the second extension section 25 are symmetrically arranged about the first reference line L3, so that the second included angle α2 between the extension direction of the first extension section 24 and the second direction X is the same as the second included angle α2 between the extension of the second extension section 25 and the second direction X. As an example, the second included angle α2 between the extension direction of the first extension section 24 and the second direction X or between the extension direction of the second extension section 25 and the second direction X is 53°, 60°, 63.4°, or 73°, which will not be enumerated in the embodiments of the present disclosure.

As shown in FIG. 5, the gate line 21 includes at least one light adjustment portion 231 and a connection portion 232 connected to the light adjustment portion 231. For example, all extension sections 23 (including the first extension section 24 and the second extension section 25) each includes at least one light adjustment portion 231 and a connection portion 232 connected to the light adjustment portion 231.

Referring to FIG. 6, a width D5 of the light adjustment portion 231 is greater than a width D6 of the connection portion 232. Due to the provision of the light adjustment portion 231, it may be possible to further increase the irregularity of the shape of the gate line 21; for example, the border of the gate line 21 is substantially in a shape of a zigzag. In other words, due to the provision of the light adjustment portion 231, it may be possible to increase the difference between the grid formed by the gate lines 21 and the grid on the liquid crystal display panel 100, which is conducive to alleviate the problem of moire pattern of the display apparatus 1000.

It will be understood that, as shown in FIG. 6, the width D5 of the light adjustment portion 231 refers to a dimension of the light adjustment portion 231 in a third reference direction M3, and the width D6 of the connection portion 232 refers to a dimension of the connection portion 232 in the third reference direction M3. The third reference direction M3 is perpendicular to an extension direction of an extension section 23 where the light adjustment portion 231 and the connection portion 232 are located.

In some embodiments, a ratio D5/D6 of the maximum width of the light adjustment portion 231 to the width of the connection portion 232 is in a range of 1.5 to 4. As shown in FIG. 6, the maximum width of the light adjustment portion 231 refers to a distance between two opposite borders of the light adjustment portion 231 in the third reference direction M3. For example, the ratio D5/D6 of the maximum width of the light adjustment portion 231 to the width of the connection portion 232 is 1.5, 2.0, 3.5 or 4, which will not be enumerated in the embodiments of the present disclosure.

For example, the width D6 of the connection portion 232 may be in a range of 5 μm to 15 μm. In this way, the resistance of the connection portion 232 is small and does not affect the signal transmission of the gate line 21; moreover, a problem of light leakage (unexpected deflection of liquid crystal molecules caused by the influence of the gate line) near the gate line 21 (the connection portion 232) of the view angle control cell 400 may be alleviated.

For example, the width of the connection portion 232 may be 5 μm, 8 μm or 15 μm, which will not be enumerated in the embodiments of the present disclosure.

In some embodiments, a difference (D5-D6) between the maximum width D5 of the light adjustment portion 231 and the width of the connection portion 232 may be in a range of 8 μm to 18 μm. For example, the difference (D5-D6) between the width D5 of the light adjustment portion 231 and the width of the connection portion 232 may be 8 μm, 13 μm or 18 μm, which will not be enumerated in the embodiments of the present disclosure.

In an example, the width of the connection portion 232 may be 8 μm, and the width of the light adjustment portion 231 may be 21 μm. In this case, the difference (D5 D6) between the width D5 of the light adjustment portion 231 and the width of the connection portion 232 is 13 μm, and the ratio D5/D6 of the maximum width of the light adjustment portion 231 to the width of the connection portion 232 is 2.625.

In some embodiments, referring to FIG. 6, a ratio L2/L1 of a length L2 of the connection portion 232 to a length L1 of the light adjustment portion 231 is in a range of 1.5 to 3.5, which helps the gate line 21 to alleviate the problem of moire pattern of the display apparatus 1000. For example, the ratio L2/L1 of the length L2 of the connection portion 232 to the length L1 of the light adjustment portion 231 is 1.5, 2.2 or 3.5, which will not be enumerated in the embodiments of the present disclosure. The length L2 of the connection portion 232 refers to a dimension of the connection portion 232 in a fourth reference direction M4, and the length L1 of the light adjustment portion 231 refers to a dimension of the light adjustment portion 231 in the fourth reference direction M4. The fourth reference direction M4 is parallel to the extension direction of the extension section 23 where the connection portion 232 and the light adjustment portion 231 are located.

For example, the length L2 of the connection portion 232 may be in a range of 50 μm to 70 μm; for instance, the length L2 of the connection portion 232 may be 50 μm, 60 μm or 70 μm. The length L1 of the light adjustment portion 231 may be in a range of 20 μm to 36 μm; for instance, the length of the light adjustment portion 231 may be 20 μm, 28 μm or 36 μm.

In some embodiments, an orthographic projection of the light adjustment portion 231 on the substrate 10 is in a shape of a hexagon (as shown in FIG. 6) or an octagon (not shown in the figures). In this way, a sharp angle will not be formed in the border of the gate line 21, which is conducive to reducing the difficulty of producing the gate lines 21. It will be understood that, the light adjustment portion 231 may also have other shapes; for example, the light adjustment portion 231 may be in a shape of a circle, an ellipse or other shapes, which will not be enumerated in the embodiments of the present disclosure.

Referring to FIG. 5, each extension section 23 includes a plurality of light adjustment portions 231 and a plurality of connection portions 232 that are alternately connected in sequence, and two ends of the extension section 23 are each a connection portion 232. In this way, a large pattern will not be formed at the connection between the first extension section 24 and the second extension section 25, which is conducive to reducing the parasitic capacitance formed between the gate line 21 and the second wiring layer 30 (such as a data line 31 and a common voltage signal line 32 mentioned below), thereby reducing signal interference between the gate line 21 and the second wiring layer 30.

As shown in FIG. 5, in the case where the first extension section 24 and the second extension section 25 are symmetrically arranged about the first reference line L3, the light adjustment portions 231 in the first extension section 24 and the light adjustment portions 231 in the second extension section 25 may also be symmetrically arranged about the first reference line L3.

In some embodiments, referring to FIG. 5, the first wiring layer 20 further includes gate patterns 51, the gate pattern 51 is connected to the gate line 21 and used to form a control electrode of the thin film transistor 50. For example, the gate pattern 51 may be disposed at the corner between the first extension section 24 and the second extension section 25. The gate pattern 51 may be in a shape of a rectangle or other shapes, which is not specifically limited in the embodiments of the present disclosure.

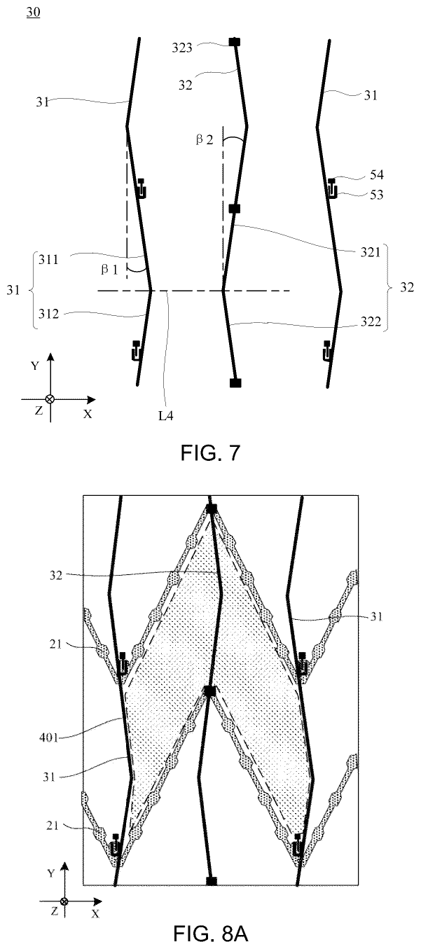

Referring to FIG. 7, the second wiring layer 30 includes a plurality of data lines 31 arranged at intervals in the second direction X. The data line 31 extends in the first direction Y as a whole. The data line 31 extending in the first direction Y as a whole means that the data line 31 extends in the first direction Y on a macro level, but the data line 31 may have a portion extending in a direction intersecting with the first direction Y on a micro level; for example, the data line 31 may be routed along a broken line. It will be understood that, the data line 31 is configured to transmit a data signal.

In some embodiments, referring to FIG. 7, the plurality of data lines 31 are each routed along a broken line. The data line 31 includes a plurality of third extension sections 311 and a plurality of fourth extension sections 312 that are alternately arranged and connected in the first direction Y. Similar to the case that the gate line 21 is routed along a broken line, the data line 31 is routed along a broken line, which helps the view angle control cell 400 to alleviate or even eliminate the problem of moiré pattern of the display apparatus 1000.

A third extension section 311 and a fourth extension section 312 that are connected to each other are symmetrically arranged about a second reference line L4, and a third included angle β1 between the extension direction of the third extension section 311 and the first direction Y or between the fourth extension section 312 and the first direction Y is in a range of 5° to 10°. It has been verified that in the case where the third included angle β1 between the extension direction of the third extension section 311 and the first direction Y or between the extension direction of the fourth extension section 312 and the first direction Y is in the above range, the risk of moiré pattern appearing in the display apparatus 1000 may be reduced to the greatest extent. The second reference line L4 is parallel to the second direction X and passes through a corner where the third extension section 311 and the fourth extension section 312 are connected.

The third extension section 311 and the fourth extension section 312 are symmetrically arranged about the second reference line L4, so that the third included angle β1 between the extension direction of the third extension section 311 and the first direction Y is the same as the third included angle β1 between the extension direction of the fourth extension section 312 and the first direction Y. For example, the third included angle β1 between the extension direction of the third extension section 311 and the first direction Y or between the fourth extension section 312 and the first direction Y is 5°, 7° or 10°, which will not be enumerated in the embodiments of the present disclosure.

In some embodiments, as shown in FIG. 7, the second wiring layer 30 may further include source patterns 53 and drain patterns 54. The source pattern 53 and the drain pattern 54 are used to respectively form the source and the drain of the thin film transistor 50. The source pattern 53 is electrically connected to a data line 31 and configured to receive a data signal transmitted by the data line 31. The source pattern 53 and the drain pattern 54 are spaced apart; for example, the source pattern 53 may be of a U-shape structure, which may increase the contact area between the source pattern 53 and a semiconductor pattern 52 mentioned below; the drain pattern 54 may be of a T-shape structure. It will be understood that, the shapes of the source pattern 53 and the drain pattern 54 may be adjusted according to actual needs.

In some embodiments, as shown in FIG. 7, the second wiring layer 30 may further include a plurality of common voltage signal lines 32 arranged at intervals in the second direction X (only one common voltage signal line 32 is illustrated in FIG. 7). The common voltage signal line 32 may be configured to transmit a common voltage signal. The common voltage signal line 32 extends in the first direction Y as a whole, which means that the common voltage signal line 32 extends in the first direction Y on a macro level, but the common voltage signal line 32 may have a portion extending in a direction intersecting with the first direction Y on a micro level; for example, the common voltage signal line 32 may be routed along a broken line.

In some embodiments, as shown in FIG. 7, the plurality of data lines 31 and the plurality of common voltage signal lines 32 are alternately arranged in the second direction X; that is, in the second direction X, every two adjacent data lines 31 is provided with a common voltage signal line 32 therebetween, every two adjacent common voltage signal lines 32 is provided with a data line 31 therebetween, and a data line 31 and a common voltage signal lines 32 adjacent thereto are symmetrically arranged. Thus, it is possible to help to improve the wiring uniformity of the second wiring layer 30 and improve the display uniformity of the display apparatus.

In some embodiments, the data line 31 and the common voltage signal line 32 adjacent thereto may be symmetrically arranged. As shown in FIG. 7, in the case where the data lines 31 and the common voltage signal lines 32 are alternately arranged, and the data line 31 and the common voltage signal line 32 adjacent to the data line 31 are symmetrically arranged, the plurality of common voltage signal lines 32 are each routed along a broken line. The common voltage signal line 32 includes a plurality of fifth extension sections 321 and a plurality of sixth extension sections 322 that are alternately arranged and connected in the first direction Y. Similar to the case that the gate line 21 is routed along a broken line, the common voltage signal line 32 is routed along a broken line, which helps the view angle control cell 400 to alleviate or even eliminate the problem of moire pattern in the display apparatus 1000.

A fifth extension section 321 and a sixth extension section 322 that are connected to each other are symmetrically arranged about the second reference line L4, and a fourth included angle β2 between the extension direction of the fifth extension section 321 and the first direction Y or between the extension direction of the sixth extension section 322 and the first direction Y is in a range of 5° to 10°. Since the data line 31 and the common voltage signal line 32 are symmetrically arranged, the fourth included angle β2 between the extension direction of the fifth extension section 321 and the first direction Y or between the extension direction of the sixth extension section 322 and the first direction Y is equal to the third included angle β1 between the extension direction of the third extension section 311 and the first direction Y or between the extension direction of the fourth extension section 312 and the first direction Y.

As shown in FIG. 7, the common voltage signal line 32 may include a widened portion 323, and a width of the widened portion 323 is greater than widths of the common voltage signal line 32 at other positions (portions except for the widened portion 323). The widened portion 323 may increase a local area of the common voltage signal line 32, thereby improving the stability and reliability of the connection between a second electrode 61 mentioned below and the common voltage signal line 32.

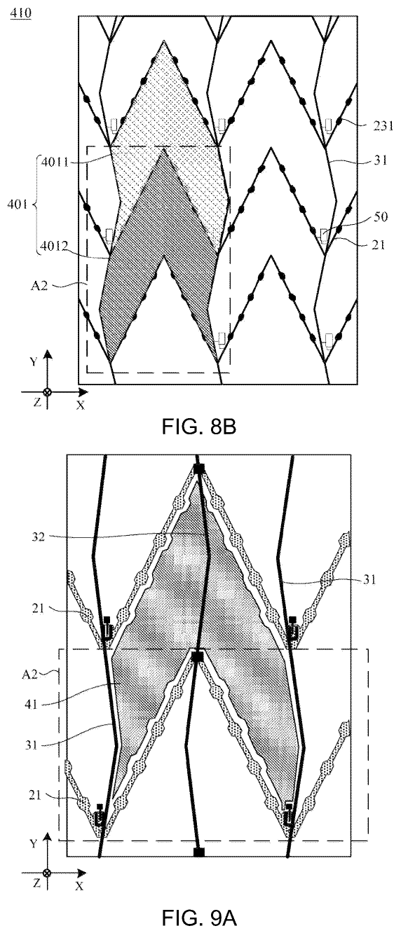

In some embodiments, referring to FIGS. 8A and 8B, orthographic projections of the plurality of gate lines 21 on the substrate 10 and orthographic projections of the plurality of data lines 31 on the substrate 10 intersect with each other, and orthographic projections of two adjacent gate lines and two adjacent data lines on the substrate define a dimming region 401, which may be understood that orthographic projections of any two adjacent data lines 31 on the substrate 10 intersect with orthographic projections of any two adjacent gate lines 21 on the substrate to define a closed grid, and the grid defines a dimming region 401. In this way, the view angle control cell 400 has a plurality of dimming regions 401 arranged in an array. It will be understood that, in the embodiments of the present disclosure, a range of the dimming region 401 may not include regions where the gate lines 21 and the data lines 31 enclosing the dimming region 401 are located; that is, the gate lines 21 and the data lines 31 do not arranged in the range of dimming region 401. The dimming region 401 is configured to switch between a sharing state and a privacy protection state; that is, the dimming region 401 is the smallest unit in which the view angle control cell 400 switches the display state.

In some embodiments, referring to FIG. 8B, in the case where the gate lines 21 and the data lines 31 are all in a shape of a broken line, the gate lines 21 and the data lines 31 may define two types of dimming regions 401 with different shapes. The two types of dimming regions 401 are a first dimming region 4011 and a second dimming region 4012; in the first direction Y, the first dimming regions 4011 and the second dimming regions 4012 are alternately arranged; and in the second direction X, the dimming regions 401 in a same row have a same shape.

For example, referring to FIG. 8A, a gate line 21 may overlap with a midpoint portion of a third extension section 311 or a fourth extension section 312 of a data line 31, which helps to obtain a data line 31 having a regular shape. A data line 31 and a gate line 21 overlap at a corner between a first extension section 24 and a second extension section 25, which helps to obtain a gate line 21 having a regular shape. On this basis, regular and uniform grids of dimming regions 401 are obtained, which may improve the dimming uniformity of the view angle control cell 400. In addition, the interference of light at various positions of the view angle control cell 400 is similar, which helps to alleviate the problem of moire pattern of the display apparatus 1000.

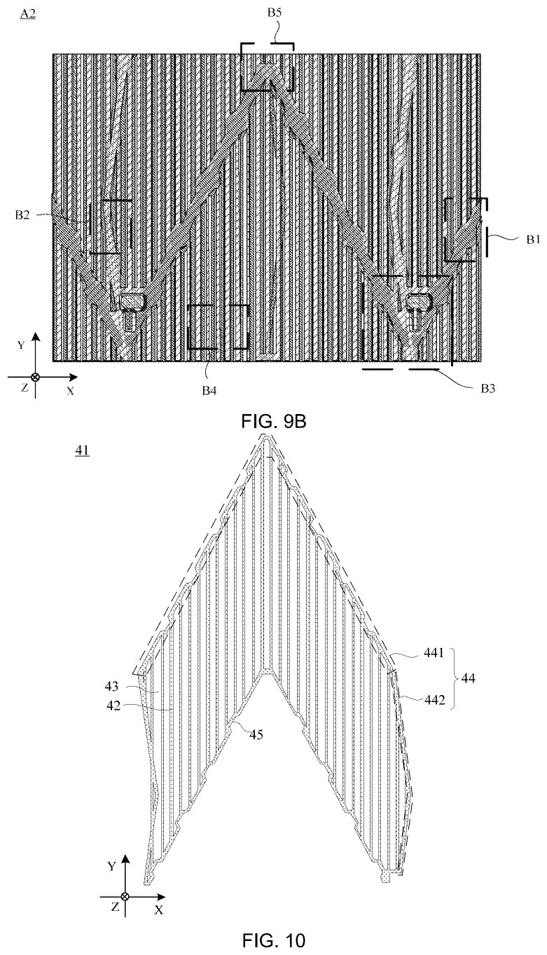

Referring to FIG. 9A, the first electrode layer 40 includes a plurality of first electrodes 41, and each dimming region 401 is provided with a first electrode 41 therein. In other words, each first electrode 41 of the plurality of first electrodes 41 is located in a respective dimming region 401, and different first electrodes 41 are located in different dimming regions 401; that is, only one first electrode 41 is located in a same dimming region 401. For example, the first electrode 41 may be a pixel electrode. In FIG. 9A, only one dimming region 401 and one first electrode 41 are illustrated.

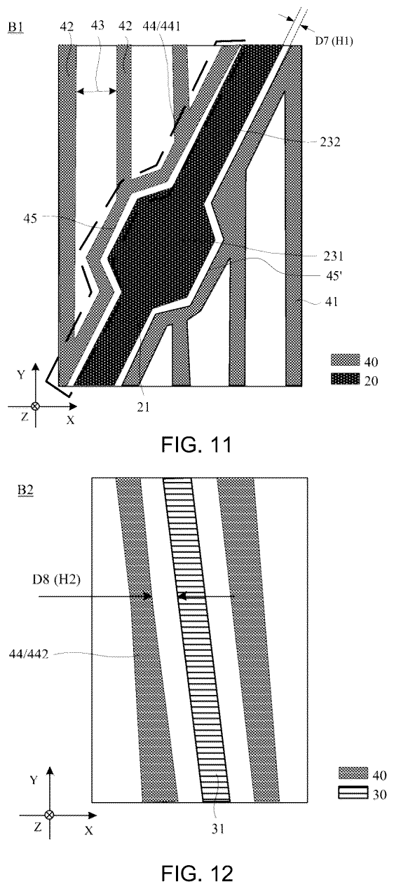

In some embodiments, referring to FIGS. 10 and 11, the first electrode 41 includes a plurality of first electrode strips 42 arranged at intervals in the second direction X and a second electrode strip 44 of which two ends are connected to each other. The first electrode strips 42 extend in the first direction Y. The second electrode strip 44 is connected to two ends of each of the first electrode strips 42 in the first direction Y to form a structure in which the second electrode strip 44 encloses the plurality of first electrode strips 42.

The second electrode strip 44 encloses the first electrode strips 42 (all first electrode strips 42 included in a first electrode 41) and is connected to (two) ends of each of the first electrode strips 42 in the first direction Y. In this way, the plurality of first electrode strips 42 may be connected as a whole through the second electrode strip 44. In a case where the first electrode 41 is electrically connected to the thin film transistor 50, as long as a portion of the first electrode 41 is electrically connected to the thin film transistor 50, the plurality of first electrode strips 42 may all be electrically connected to the thin film transistor 50, so that the thin film transistor 50 may charge the plurality of first electrode strips 42. The second electrode strip 44 may also be considered as a portion of the first electrode 41 formed at the edge, or a portion of the first electrode 41 excluding the first electrode strips 42.

In some embodiments, referring to FIG. 10, the second electrode strip 44 includes two fourth electrode sub-strips 441 oppositely arranged in the first direction Y and two fifth electrode sub-strips 442 oppositely arranged in the second direction X. Referring to FIGS. 9B and 11, an extension direction of the fourth electrode sub-strip 441 is parallel to the extension direction of the gate line 21. Referring to FIG. 12, an extension direction of the fifth electrode sub-strip 442 is parallel to the extension direction of the data line 31.

Referring to FIG. 11, orthographic projections of the fourth electrode sub-strip 441 and the gate line 21 on the substrate 10 have a first spacing H1 therebetween. Referring to FIG. 12, orthographic projections of the fifth electrode sub-strip 442 and the data line 31 on the substrate 10 have a second spacing H2 therebetween. The first interval H1 and the second interval H2 may be equal or not equal, which is not specifically limited in the embodiments of the present disclosure. That is, there is a spacing between an outer border of the second electrode strip 44 and a border of the dimming region 401, which helps to reduce signal interference between the first electrode 41 and the gate line 21 and data line 31, thereby making the electric field generated by the first electrode 41 and the second electrode layer 60 evenly distributed in the dimming region 401.

In some embodiments, referring to FIG. 10, the fourth electrode sub-strip 441 has a zigzag structure, or the fourth electrode sub-strip 441 has a concave-convex structure, which helps to improve the irregularity of the grid formed by the fourth electrode sub-strips 441, and thereby facilitating the view angle control cell 400 alleviating or even eliminating the problem of the moire pattern in the display apparatus 1000.

In some embodiments, referring to FIGS. 10 and 11, a first recess 45 is provided at an edge of the fourth electrode sub-strip 441 proximate to the gate line 21, and an orthographic projection of the first recess 45 on the substrate and an orthographic projection of the gate line 21 on the substrate have a spacing therebetween.

For example, there is a spacing between a border of the first electrode 41 and a border of the dimming region 401 (as shown in FIG. 11). Referring to FIG. 11, an orthographic projection of the first electrode 41 on the substrate 10 and the orthographic projection of the gate line 21 on the substrate 10 have a spacing D7 therebetween; referring to FIG. 12, the orthographic projection of the first electrode 41 on the substrate 10 and the orthographic projection of the data line 31 on the substrate 10 have a spacing D8 therebetween. In this way, in the direction perpendicular to the substrate 10, the first electrode 41 has no portion opposite to the gate line 21 and data line 31, so that no parasitic capacitance will be formed between the first electrode 41 and the gate line 21 and data line 31, which may reduce the influence of fluctuation in voltages of the gate line 21 and data line 31 on the voltage of the first electrode 41.

In some embodiments, referring to FIG. 11, in the orthographic projection of the first electrode 41 on the substrate 10, a second recess 45′ is provided on a side of the first electrode 41 proximate to the light adjustment portion 231; a shape of the second recess 45′ is the same as a shape of the light adjustment portion 231 on a side proximate to the first electrode 41, and a spacing between the second recess 45′ and the light adjustment portion 231 is equal to a spacing between the first electrode 41 and the connection portion 232. That is, the first electrode 41 is arranged with an equal spacing from the light adjustment portion 231 and the connection portion 232, which may alleviate the problem of signal interference between the light adjustment portion 231 of the gate line 21 and the first electrode 41.

In some embodiments, referring to FIG. 10, a second slit 43 is provided between two adjacent first electrode strips 42. The second slit 43 may also extend in the first direction Y. In the first direction Y, there is a spacing between an end of the second slit 43 and the border of the first electrode 41; in other words, in the first direction Y, the second slit 43 does not penetrate the first electrode 41, and two adjacent first electrode strips 42 may be connected as a whole through the edge (the second electrode strip) of the first electrode 41. Due to the provision of the second slit 43, it may be possible to not only increase the light transmittance of the first electrode layer 40 but also reduce the area of the first electrode 42, which reduces the area of the first electrode 42 directly facing the common electrode layer 60. In this way, the parasitic capacitance between the first electrode 42 and the common electrode layer 60 may be reduced, thereby improving the efficiency of charging the first electrode 42.

For example, orthographic projections of the first electrode strips 42 on the substrate 10 are non-overlapping with an orthographic projection of the second electrode layer 60 on the substrate 10. In this way, the risk of parasitic capacitance being formed between the first electrode strips 42 and the second electrode layer 60 may be reduced, which may reduce the influence of the second electrode layer 60 on the rate of charging the first electrode strips 42, thereby improving the efficiency of charging the first electrode strips 42.

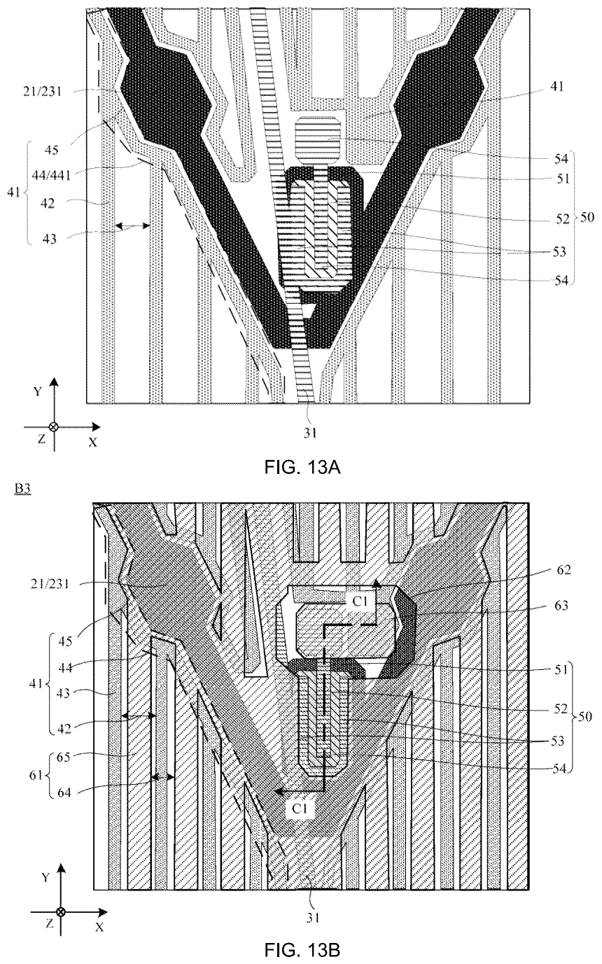

Referring to FIG. 8B, each dimming region is provided with a thin film transistor 50 therein. That is, each thin film transistor 50 of the plurality of thin film transistors 50 is located in one dimming region 401, and different thin film transistors 50 are located in different dimming regions 401. Referring to FIGS. 13A and 13B, a thin film transistor 50 is electrically connected to a data line (one data line 31 of two data lines 31 that enclose the dimming region 401 where the thin film transistor 50 is located), a gate line 21 (one gate line 21 of two gate lines 21 that enclose the dimming region 401 where the thin film transistor 50 is located), and a first electrode 41 (located in the dimming region 401 where the thin film transistor 50 is located). The thin film transistor 50 is configured to transmit a data signal from the data line 31 to the first electrode 41 under the control of a scanning signal from the gate line 21.

Referring to FIG. 13A, the thin film transistor 50 may include a gate pattern 51, a semiconductor pattern 52, a source pattern 53 and a drain pattern 54. The gate pattern 51 is disposed in the first wiring layer 20, electrically connected to the gate line 21, and configured to receive a scanning signal from the gate line 21. The semiconductor pattern 52 may also be referred to as an active layer pattern and is located between the first wiring layer 20 and the second wiring layer 30. The source pattern 53 and the drain pattern 54 are located in the second wiring layer 30; the source pattern 53 is electrically connected to the data line 31, and the drain pattern 54 is spaced apart from the source pattern 53; that is, the drain pattern 54 is not in contact with the source pattern 54.

An orthographic projection of the gate pattern 51 on the substrate 10 covers orthographic projections of the semiconductor pattern 52 and the source pattern 53 on the substrate 10, and partially overlaps with an orthographic projection of the drain pattern 54 on the substrate 10. The orthographic projection of the drain pattern on the substrate 10 is non-overlapping with an orthographic projection of the first electrode 41 on the substrate 10. Referring to FIG. 13A, a material of the semiconductor pattern 52 may be amorphous silicon (a-Si), oxide, or low-temperature polycrystalline silicon (LTPS), which is not specifically limited in the embodiments of the present disclosure.

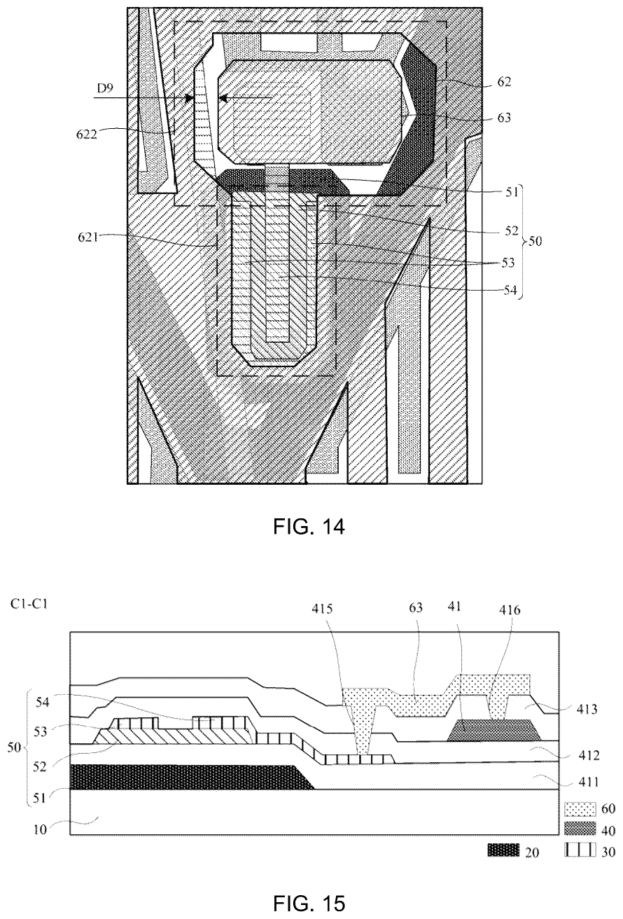

Referring to FIGS. 13B and 14, the second electrode layer 60 includes a second electrode 61. For example, the second electrode 61 may be a common electrode 61, and the second electrode 61 may be electrically connected to, for example, a common voltage signal line (not shown in these figures). An orthographic projection of the second electrode 61 on the substrate 10 is at least partially non-overlapping with the orthographic projection of the first electrode 41 on the substrate 10, and the orthographic projection of the second electrode 61 on the substrate 10 is at least partially non-overlapping with an orthographic projection of the thin film transistor 50 on the substrate 10. In this way, an area of the second electrode 61 directly facing the first electrode 41 and an area of the second electrode 61 directly facing the thin film transistor 50 may be reduced, which may reduce the parasitic capacitance formed between the second electrode 61 and the first electrode 41 and the parasitic capacitance formed between the second electrode 61 and the thin film transistor 50, thereby reducing the bad effect of the second electrode 61 on the first electrode 41 and the thin film transistor 50.

It will be understood that, the parasitic capacitance will have a hysteresis effect on signal transmission. For example, the second electrode 61 is at least partially non-overlapping with the first electrode 41, so that the parasitic capacitance formed between the two may be reduced. In this way, in the process of the thin film transistor 50 charging (transmitting a data signal to) the first electrode 41, the efficiency of charging the first electrode 41 may be increased; that is, the first electrode 41 may be charged fast and sufficiently. The second electrode 61 is at least partially non-overlapping with the thin film transistor 50, which may reduce the risk of parasitic capacitance being formed between the second electrode 61 and the thin film transistor 50, thereby increasing the response speed of the thin film transistor 50.

In some embodiments, referring to FIGS. 13B and 14, the second electrode 61 includes a plurality of avoidance openings 62. Each dimming region is provided with an avoidance opening 62 therein, and an orthographic projection of the avoidance opening 62 on the substrate 10 at least partially overlaps with the orthographic projection of the thin film transistor 50 on the substrate 10; that is, a border of the avoidance opening 62 surrounds at least a portion of the thin film transistor 50, and at least a portion of the thin film transistor 50 is located in the avoidance opening 62, which helps to reduce an overlapping region of the orthographic projections of the second electrode 61 and the thin film transistor 50 on the substrate 10, thereby reducing the parasitic capacitance formed between the second electrode 61 and the thin film transistor 50. As a result, the bad effect of the second electrode 61 on the thin film transistor 50 may be reduced, thereby improving the response speed of the thin film transistor 50.

For example, as shown in FIGS. 13B and 14, the avoidance opening 62 includes a first opening portion 621, a shape of a border of the first opening portion 621 is substantially the same as a shape of a border of the semiconductor pattern 52, and an orthographic projection of the first opening portion 621 on the substrate 10 is located within an orthographic projection of the semiconductor pattern 52 on the substrate. The border of the semiconductor pattern 52 surrounds the border of the first opening portion 621. In this way, the risk of the first opening portion 621 exposing the gate line 21 and the data line 31 may be reduced, thereby reducing the influence of electric field formed by the gate line 21 and the data line 31 on the first liquid crystal layer.

For example, as shown in FIG. 14, the border of the first opening portion 621 and the border of the semiconductor pattern 52 is substantially in a shape of a rectangle; the border of the first opening portion 621 and the border of the semiconductor pattern 52 have a spacing therebetween, and in a circumferential direction of the first opening portion 621, the spacing between the border of the first opening portion 621 and the border of the semiconductor pattern 52 is substantially the same; that is, the spacing between any position at the border of the first opening portion 621 and the border of the semiconductor pattern 52 is substantially the same.

In some embodiments, as shown in FIG. 14, in the case where the orthographic projection of the first electrode 41 on the substrate 10 is non-overlapping with the orthographic projection of the drain pattern 54 on the substrate 10, the second electrode layer 60 further includes a transfer block 63, and the transfer block 63 is electrically connected to the drain pattern 54 and the first electrode 41. That is, the drain pattern 54 is electrically connected to the first electrode 41 through the transfer block 63, which is conducive to simplifying the manufacturing process of the array substrate 410 and reducing the manufacturing difficulty and cost of the array substrate 410.

It will be understood that, referring to FIG. 15, the array substrate 410 further includes an insulating layer located between two adjacent conductive layers. For example, as shown in FIG. 15, the array substrate 410 further includes a gate insulating layer 411 between the first wiring layer 20 and the semiconductor pattern 52, a first passivation layer (PVX1) 412 located between the second wiring layer 30 and the first electrode layer 40, and a second passivation layer (PVX2) 413 located between the first electrode layer 40 and the second electrode layer 60. A material of the first passivation layer 412 may be the same as a material of the second passivation layer 413; for example, the material of the first passivation layer 412 and the material of the second passivation layer 413 may both include silicon nitride and/or silicon oxide.

Referring to FIG. 15, the array substrate 410 further includes a second via hole 415 penetrating the first passivation layer 412 and the second passivation layer 413, and a third via hole 416 penetrating the second passivation layer 413. An orthographic projection of the second via hole 415 on the substrate 10 at least partially overlaps with orthographic projections of the drain pattern 54 and the transfer block 63 on the substrate 10, so that the transfer block 63 may be electrically connected to the drain pattern 54 through the second via hole 415. An orthographic projection of the third via hole 416 on the substrate 10 at least partially overlaps with orthographic projections of the transfer block 63 and the first electrode 41 on the substrate 10, so that the transfer block 63 may be electrically connected to the first electrode 41 through the third via hole 416.

With the above design of the transfer block 63, in the process of manufacturing the array substrate 410, the first electrode layer 40 and the second passivation layer 413 may be sequentially formed directly on the first passivation layer 412 after the first passivation layer 412 is formed, and then the second via hole 415 and the third via hole 416 may be formed simultaneously in a single etching process. In comparison with the solution that the first electrode 41 is directly electrically connected to the drain pattern 54 through a via hole (e.g., a via hole only penetrating the first passivation layer), in the above design, at least one process of etching the via hole may be saved; that is, the manufacturing processes of the array substrate 410 may be simplified, thereby reducing the manufacturing cost of the array substrate 410.

As an example, embodiments of the present disclosure provide a manufacturing method of an array substrate, and the manufacturing method includes S100 to S500.

In S100, a first wiring layer, a gate insulating layer, a semiconductor layer, and a second wiring layer are sequentially formed on a substrate.

The structures of the first wiring layer, the gate insulating layer, the semiconductor layer and the second wiring layer refer to the above description, and will not be repeated here.

In S200, a first initial passivation layer is formed on the second wiring layer.

The first initial passivation layer is of a continuous whole layer structure.

In S300, a first electrode layer and a second initial passivation layer are sequentially formed on the first initial passivation layer.

The structure of the first electrode layer refers to the above description and will not be repeated here. The second initial passivation layer is of a continuous whole layer structure.

In S400, the second initial passivation layer and the first initial passivation layer are patterned to form a second passivation layer and a first passivation layer.

For example, a second via hole 415 and a third via hole 416 may be formed in the second initial passivation layer and the first initial passivation layer simultaneously in a single etching process.

In S500, a second electrode layer is formed on the second passivation layer.

The second electrode layer includes a transfer block, and the transfer block is electrically connected to a drain and a first electrode respectively through the second via hole and the third via hole. It can be seen that there is no need to separately form a via hole in the first initial passivation layer, and the second via hole 415 and the third via hole 416 may be formed in a single process, which may simplify the manufacturing processes of the array substrate 410, thereby reducing the manufacturing cost of the array substrate 410.

For example, as shown in FIG. 14, a border of the transfer block 63 and a border of a second opening portion 622 are substantially in a shape of a rectangle, and the corners of the rectangle are chamfered. The second opening portion 622 and the transfer block 63 have a spacing therebetween, and in a circumferential direction of the second opening portion 622, a spacing between the border of the second opening portion 622 and the transfer block 63 is substantially the same.

The spacing D9 between the border of the transfer block 63 and the border of the second opening portion 622 is in a range of 6 μm to 20 μm. In this way, not only the electrical insulation between the transfer block 63 and the second electrode 61 may be ensured to reduce the signal interference between the transfer block 63 and the second electrode 61, but also a local region where liquid crystals cannot be controlled to deflect may be prevented from existing in the dimming region 401. For example, the spacing D9 between the border of the transfer block 63 and the border of the second opening portion 622 may be 6 μm, 11.5 μm, 18 μm, or 20 μm, which is not specifically limited in the embodiments of the present disclosure.

It will be understood that, the distance D9 between the border of the transfer block 63 and the border of the second opening portion 622 may be set to be in the range of 6 μm to 20 μm.

In some embodiments, referring to FIG. 14, an orthographic projection of the transfer block 63 on the substrate 10 is non-overlapping with the orthographic projections of the data line 31 and the gate line 21 on the substrate 10. In this way, the risk of parasitic capacitance being formed between the transfer block 63 and the data line 31 and gate line 21 may be reduced, which reduces the fluctuation in the voltage of the transfer block 63 caused by the fluctuation in the voltages of the data line 31 and gate line 21 to improve the stability of the voltage of the first electrode 41, thereby improving the stability of a light transmission state in the dimming region 401.

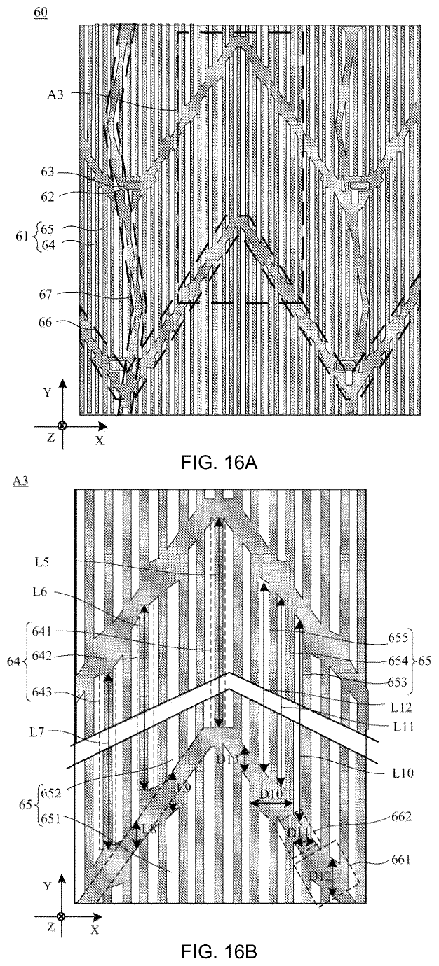

In some embodiments, referring to FIG. 16A, the second electrode 61 includes: a plurality of third electrode strips 64 arranged at intervals in the second direction X, and fourth electrode strips 66 connected to ends of the third electrode strips 64. The third electrode strips 64 extend in the first direction Y. An extension direction of a fourth electrode strip 66 is parallel to an extension direction of a gate line 21, and an orthographic projection of the fourth electrode strip 66 on the substrate 10 at least partially overlaps with an orthographic projection of the gate line 21 on the substrate 10. In the first direction Y, ends of the third electrode strips 64 are connected to the fourth electrode strips 66, so that third electrode strips 64 located in different dimming regions 401 are connected through the fourth electrode strips 66.

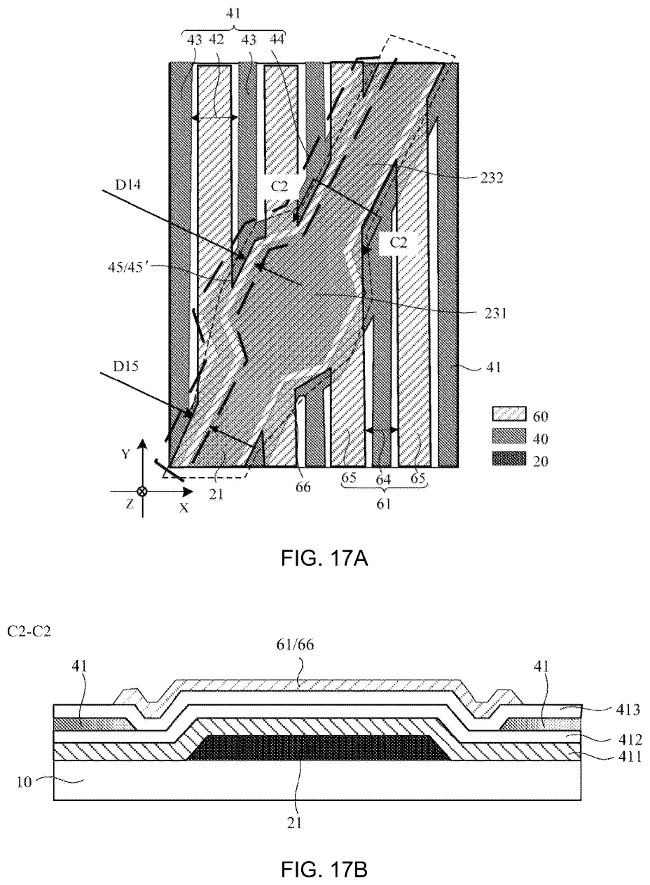

For example, excluding a portion of the orthographic projection of the gate line 21 on the substrate 10 that is exposed by an avoidance opening 62, the remaining portion of the orthographic projection of the gate line 21 on the substrate 10 is located within the orthographic projection of the fourth electrode strip 66 on the substrate 10. As an example, referring to FIGS. 17A and 17B, a border of the orthographic projection of the gate line 21 on the substrate 10 is located inside of a border of the orthographic projection of the fourth electrode strip 66 on the substrate 10 and has a spacing from the border of the orthographic projection of the fourth electrode strip 66 on the substrate 10. That is, a width (a dimension in a direction perpendicular to the extension direction of the fourth electrode strip 66) of the fourth electrode strip 66 is greater than a width of the gate line 21, so that the fourth electrode strip 66 may completely cover the gate line 21 and completely shield the electric field generated by the gate line 21.

In some embodiments, referring to FIG. 16B, the fourth electrode strip 66 includes at least one protruding portion 661 and a straight portion 662 connected to the protruding portion 661. For example, the fourth electrode strip 66 includes a plurality of protruding portions 661 and a plurality of straight portions 662 that are alternately connected in sequence. A dimension D10 of the protruding portion 661 in the second direction X is greater than a dimension D11 of the straight portion 662 in the second direction X, and a dimension D12 of the protruding portion 661 in the first direction Y is greater than a dimension D13 of the straight portion 662 in the first direction Y. A border of the fourth electrode strip 66 may be in a shape of a zigzag or has a concave-convex structure for covering the gate line 21 well to reduce the influence of the electric field formed by the gate line 21 on the first liquid crystal layer.

For example, referring to FIG. 17A, in the case where the gate line 21 includes a plurality of light adjustment portions 231, the shape of the protruding portion 661 may be the same as the shape of the light adjustment portion 231; each protruding portion 661 corresponds to a light adjustment portion 231, and an orthographic projection of the protruding portion 661 on the substrate 10 covers an orthographic projection of the light adjustment portion 231 corresponding to the protruding portion 661 on the substrate 10. In addition, a spacing D14 between the orthographic projections of the protruding portion 661 and the light adjustment portion 231 on the substrate may be equal to a spacing D15 between the orthographic projections of the connection portion 232 and the straight portion 662 on the substrate; that is, the spacing between different portions of the orthographic projection of the fourth electrode strip 66 on the substrate 10 and the orthographic projection of the gate line 21 on the substrate 10 are substantially equal. In this way, the fourth electrode strip 66 may shield the electric field generated by the gate line 21, thereby reducing the risk of the electric field generated by the light adjustment portion 231 affecting the first liquid crystal layer.

Referring to FIG. 16B, multiple third electrode strips 64 located in a same dimming region include first electrode sub-strips 641, second electrode sub-strips 642 and third electrode sub-strips 643. Two ends of a first electrode sub-strip 641 in the first direction Y are respectively connected to straight portions 662. In the first direction Y, an end of a second electrode sub-strip 642 is connected to a straight portion 662, and another end of the second electrode sub-strip 642 is connected to a protruding portion 661. Two ends of a third electrode sub-strip 643 in the first direction Y are respectively connected to protruding portions 661. A dimension L5 of the first electrode sub-strip 641 in the first direction Y is greater than a dimension L6 of the second electrode sub-strip 642 in the first direction Y, and the dimension L6 of the second electrode sub-strip 642 in the first direction Y is greater than a dimension L7 of the third electrode sub-strip 643 in the first direction Y.

Referring to FIG. 16B, the second electrode 61 further includes a first slit 65 located between two adjacent third electrode strips 64. Two first slits 65 adjacent in the first direction Y are respectively a first sub-slit 651 and a second sub-slit 652. The first sub-slit 651 and the second sub-slit 652 are respectively located on two sides of a fourth electrode strip 66 and respectively connected to two opposite edges of the fourth electrode strip 66. A distance L8 between a first sub-slit 651 and a second sub-slit 652 that are respectively located on two sides of a straight portion 662 in the first direction Y is less than a distance L9 between a first sub-slit 651 and a second sub-slit 652 that are respectively located on two sides of a protruding portion 661 in the first direction Y. With continued reference to FIG. 16B, in a same dimming region, multiple first slits 65 include third sub-slits 653, fourth sub-slits 654 and fifth sub-slits 655. Two ends of a third sub-slit 653 in the first direction Y are respectively connected to straight portions 662. In the first direction Y, an end of a fourth sub-slit 654 is connected to a straight portion 662, and another end of the fourth sub-slit 654 is connected to a protruding portion 661. Two ends of a fifth sub-slit 655 in the first direction Y are respectively connected to protruding portions 661. A dimension L10 of the third sub-slit 653 in the first direction Y is greater than a dimension L11 of the fourth sub-slit 654 in the first direction Y, and the dimension L11 of the fourth sub-slit 654 in the first direction Y is greater than a dimension L12 of the fifth sub-slit 655 in the first direction Y.

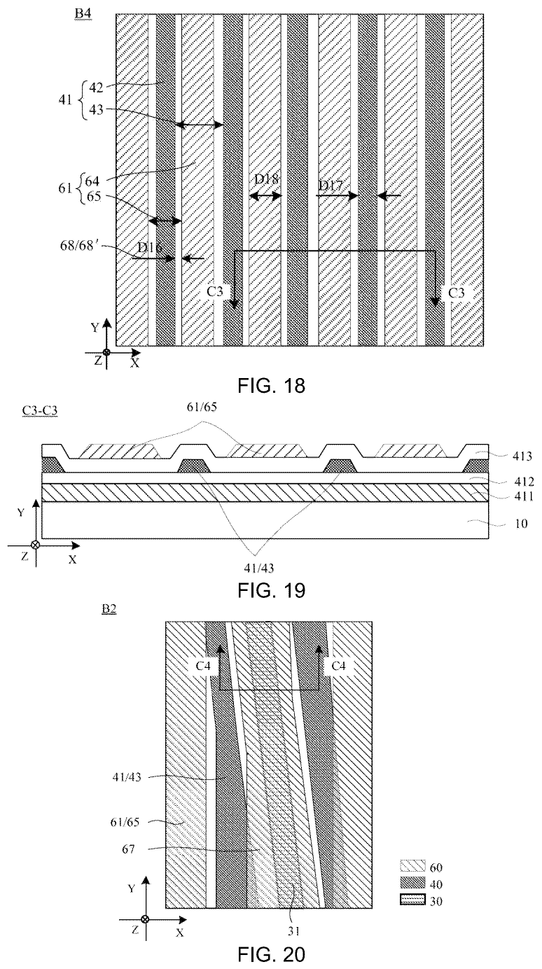

Referring to FIGS. 18 and 19, the second electrode 61 further includes a first slit 65 located between two adjacent third electrode strips 64. The first electrode 41 includes a plurality of first electrode strips 42 arranged at intervals in the second direction X and a second slit 43 located between two adjacent first electrode strips 42. The orthographic projections of the first slit 65 and the second slit 43 on the substrate partially overlap, and the overlapping portion of the first slit 65 and the second slit 43 defines a third slit 68. A dimension D16 of the third slit 68 in the second direction X is less than a dimension D17 of the first electrode strip 42 in the second direction X and a dimension D18 of the third electrode strip 64 in the second direction X.

It will be understood that, the extension direction of the second slit 43 is parallel to the extension direction of the first slit 65, and both the second slit 43 and the first slit 65 extend in the first direction Y, which helps to improve the light transmittance of the view angle control cell 400. However, in some other embodiments, the extension direction of the second slit 43 and the extension direction of the first slit 65 may have a certain angle with respect to the first direction Y, which is not specifically limited in the embodiments of the present disclosure.

In some embodiments, as shown in FIG. 18, a fourth slit 68′ exists between orthographic projections of a first electrode strip 42 and an adjacent third electrode strip 64 on the substrate 10, and the fourth slit 68′ is located in both a second slit 43 and a first slit 65. For example, dimensions D16 of multiple fourth slits 68′ in the second direction X are the same; that is, the plurality of first electrode strips 42 and the plurality of third electrode strips 64 are arranged in the second direction X with an equal spacing. In other words, orthographic projections of the first electrode strips 42 on the substrate 10 and orthographic projections of the third electrode strips 64 on the substrate 10 are alternately arranged in the second direction X, and the first electrode strips 42 are non-overlapping with the third electrode strips 64; for example, a third electrode strip 64 is arranged between every two adjacent first electrode strips 42, and a first electrode strips 42 is arranged between every two adjacent third electrode strips 64. In this way, the electric field generated by the first electrodes 41 and the second electrode 61 is evenly distributed; furthermore, the area of the overlapping region of orthographic projections of the first electrode 41 and the second electrode 61 on the substrate 10 may be reduced to the greatest extent, which reduces the parasitic capacitance formed between the first electrode 41 and the second electrode 61, thereby reducing the influence of the second electrode 61 on the efficiency of charging the first electrode 41.

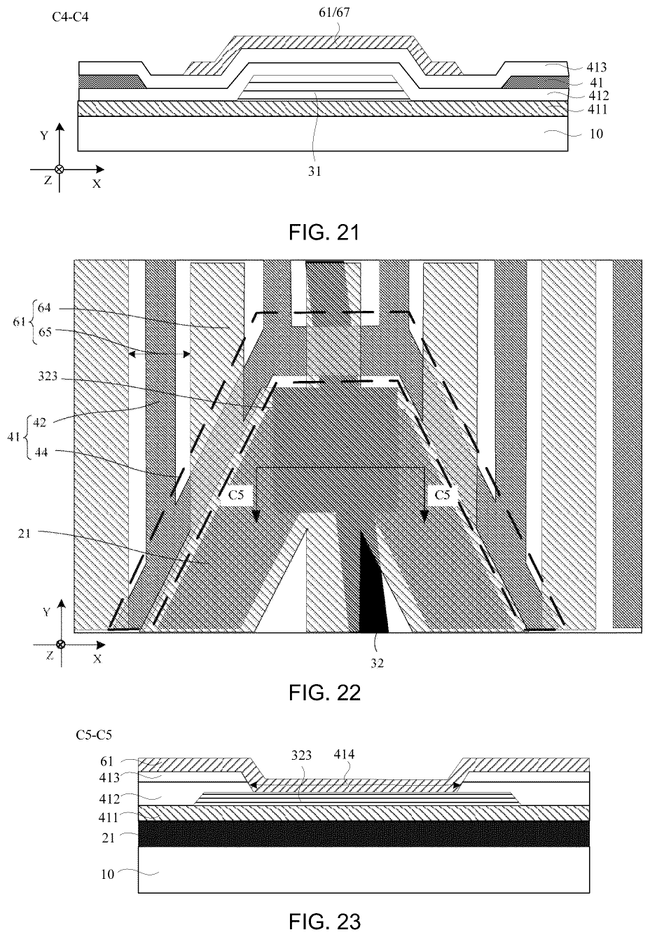

In some embodiments, as shown in FIG. 16A, the second electrode 61 further includes fifth electrode strips 67. As shown in FIGS. 20 and 21, an extension direction of a fifth electrode strip 67 is parallel to the extension direction of the data line 31, and an orthographic projection of the fifth electrode strip 67 on the substrate 10 covers at least a portion of the orthographic projection of the data line 31 on the substrate 10.

For example, excluding a portion of the orthographic projection of the data line 31 on the substrate 10 that is exposed by an avoidance opening 62, the remaining portion of the orthographic projection of the data line 31 on the substrate 10 is located within the orthographic projection of the fifth electrode strip 67 on the substrate 10.

For example, referring to FIGS. 20 and 21, a border of the orthographic projection of the data line 31 on the substrate 10 is located inside of a border of the orthographic projection of the fifth electrode strip 67 on the substrate 10, and has a spacing from the border of the orthographic projection of the fifth electrode strip 67 on the substrate 10. In other words, a width (a dimension in a direction perpendicular to the extension direction of the fifth electrode strip 67) of the fifth electrode strip 67 is greater than the width of the data line 31. In this way, the fifth electrode strip 67 may completely cover the data line 31 and completely shield the electric field generated by the data line 31.

In some embodiments, since the common voltage signal line 32 is electrically connected to the second electrode 61 (the second electrode layer 60), i.e., there is no voltage difference between the common voltage signal line 32 and the second electrode 61, there will be no voltage difference and parasitic capacitance between the two. On this basis, the orthographic projection of the second electrode 61 on the substrate 10 may overlap with an orthographic projection of the common voltage signal line 32 on the substrate 10 or may be separated from the orthographic projection of the common voltage signal line 32 on the substrate 10 without overlapping, either of which will not affect the electric field distribution in the dimming region 401. For example, as shown in FIG. 22, the orthographic projection of the second electrode 61 on the substrate 10 partially overlaps with the orthographic projection of the common voltage signal line 32 on the substrate 10 and is separated from a portion of the common voltage signal line 32 without overlapping.

As shown in FIGS. 22 and 23, the array substrate 410 further includes a first via hole 414 penetrating the first passivation layer 412 and the second passivation layer 413, and an orthographic projection of the first via hole 414 on the substrate 10 partially overlaps with orthographic projections of both the common voltage signal line 32 and the second electrode 61 on the substrate 10, so that the second electrode 61 is electrically connected to the common voltage signal line 32 through the first via hole 414.

In the case where the common voltage signal line 32 includes the widened portion 323, the widened portion 323 is electrically connected to the second electrode 61. The first via hole 414 exposes the widened portion 323 of the common voltage signal line 32. The widened portion 323 may increase the contact area between the second electrode 61 and the common voltage signal line 32, which is conducive to improving the stability of connection between the common voltage signal line 32 and the second electrode 61. The orthographic projection of the widened portion 323 on the substrate 10 is located within the orthographic projection of the gate line 21 on the substrate, which is conducive to reducing the blocking of the light by the widened portion 323 to improve the light transmittance of the array substrate 410.

When the display apparatus 1000 is in operation, the first liquid crystal layer 430 of the view angle control cell 400 is configured to adjust deflection directions of liquid crystal molecules in the first liquid crystal layer 430 in each dimming region 401 under the control of the thin film transistors 50 of the array substrate 410. For example, when the display apparatus 1000 is in operation, the view angle control cell 400 transmits a voltage signal to a first electrode 41 through a thin film transistor 50, and a common voltage signal line 32 provides a common voltage for the second electrode 61, then a voltage difference is formed between the first electrode 41 and the second electrode 61, so that an electric field is generated in the dimming region 401. The liquid crystal molecules located in the dimming region 401 deflect due to the action of the above-mentioned electric field. On this basis, the light entering each dimming region 401 is controlled to be emitted from the first liquid crystal layer 430 in a scattered state or a vertical state; that is, the light entering each dimming region 401 is adjusted. The view angle control cell 400 provided by the embodiments of the present disclosure may accurately control deflection directions of liquid crystal molecules in each dimming region 401, thereby controlling the light propagation direction of each dimming region 401 and accurately controlling a light transmission state (the transparent state or the scattering state) of each dimming region 401. In this way, the view angle control cell 400 can adjust a display state (the sharing state or the privacy protection state) of the region of the liquid crystal display panel 100 corresponding to each dimming region 401.

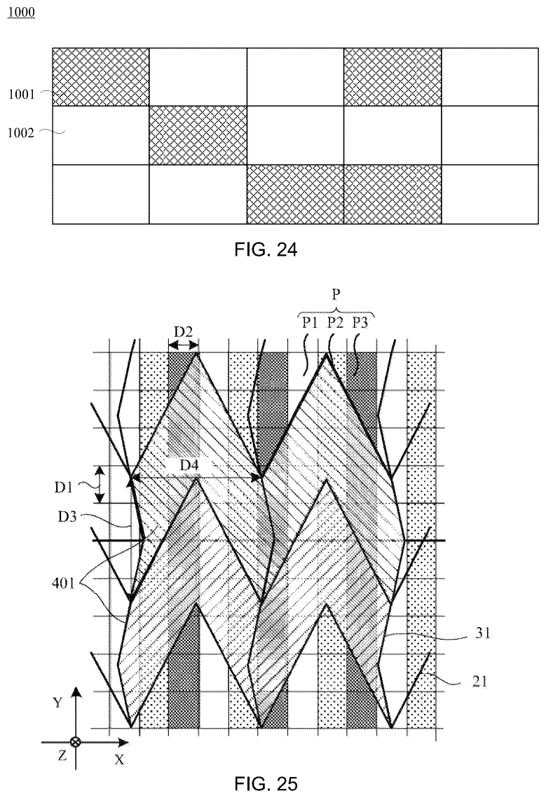

The deflection directions of liquid crystal molecules in different dimming regions 401 may be the same or different; that is, the propagation directions of light passing through different dimming regions 401 may be the same or different. On this basis, display states of regions of the liquid crystal display panel 100 corresponding to different dimming regions 401 may be adjusted; that is, the liquid crystal display panel 100 may display an image in different regions in the sharing state and the privacy protection state, respectively. Especially in large-size display apparatuses, users may adjust the display states of different regions as needed; for example, referring to FIG. 24, an image may be displayed in different regions in the privacy protection state and the sharing state at the same time, which helps to improve the user experience. In FIG. 24, the display apparatus 1000 includes privacy protection display regions 1001 and sharing display regions 1002. The privacy protection display regions 1001 and the sharing display regions 1002 may be arranged in any shape, quantity and relative positional relationship, which is not specifically limited in the embodiments of the present disclosure.

In the embodiments of the present disclosure, the dimming region 401 is the smallest dimming unit of the view angle control cell 400, and the dimming precision of the view angle control cell 400 may be adjusted by adjusting the size (area) of the dimming region 401. In this way, the minimum region in which the display apparatus 1000 can perform partitioned display may be adjusted; that is, the precision of the partitioned display of the display apparatus 1000 is related to the size of the dimming region 401. Dimming refers to adjusting the propagation direction of light passing through the view angle control cell 400, and partitioned display refers to that the display states (the sharing state or the privacy protection state) of different regions are different. For example, in a case where each dimming region 401 of the view angle control cell 400 is arranged opposite to 10 sub-pixels of the liquid crystal display panel 100, the minimum region for the liquid crystal display panel 100 to perform partitioned display is 10 sub-pixels. Based on this, for example, the size of the dimming region 401 and the size of the sub-pixel may be set to the same order of magnitude (e.g., the difference in length of a single side is less than 10 times the shorter one). In this way, the display apparatus 1000 may achieve pixel-level dimming, which enables the display apparatus to achieve privacy protection display in partition with any size, thereby improving the display flexibility of the display apparatus to improve the user experience.

In some embodiments, referring to FIG. 25, for each sub-pixel P, a dimension in the first direction Y is denoted as D1, and a dimension in the second direction X is denoted as D2; for the dimming region 401, a dimension in the first direction Y is denoted as D3, and a dimension in the second direction X is denoted as D4. D3=N×D1+M, D4=O×D2+P, where 2≤N≤8, and N is a positive integer, 0.1 μm≤M≤0.8 μm, 2≤O≤8, and O is a positive integer, and 0.1 μm≤P≤0.8 μm. That is, the dimension of the dimming region 401 in the first direction Y is equal to a sum of a value of (2-8) times the dimension of the sub-pixel P in the first direction Y and a value of (0.1-0.8) μm, and the dimension of the dimming region 401 in the second direction X is equal to a sum of a value of (2-8) times the dimension of the sub-pixel P in the second direction X and a value of (0.1-0.8) μm. N and O may be the same or different, and M and P may be the same or different, which are not limited in the embodiments of the present disclosure. For example, D3=4×D1+0.2 μm, and D4=4×D2+0.2 μm.

Based on the above setting for the size, the display apparatus 1000 may achieve pixel-level dimming, which is conducive to improving the dimming precision of the display apparatus 1000; moreover, the dimension of the dimming region 401 is equal to a sum of a value of an integer multiple of the dimension of the sub-pixel P and a value of (0.1-0.8) μm, which may avoid a situation where orthographic projections of the dimming regions 401 on the liquid crystal display panel 100 and the plurality of sub-pixels P are periodically distributed, thereby alleviating or even eliminate the problem of rainbow mura appearing in the liquid crystal display panel 10.

In some embodiments, the view angle control cell 400 further includes a plurality of spacers (not shown in the figures). The plurality of spacers are located in the liquid crystal cell between the array substrate 410 and the opposite substrate 420, and configured to support the array substrate 410 and the opposite substrate 420 to improve the uniformity of the thickness of the liquid crystal cell. Each spacer includes an end surface in contact with the array substrate 410, and an orthographic projection of the end surface on the substrate 10 is located within an orthographic projection of a light adjustment portion 231 on the substrate 10. That is, a spacer may also be disposed on the light adjustment portion 231, and the light adjustment portion 231 helps to improve the flatness of a region of the array substrate 410 where the spacer is disposed to increase the pressure bearing capacity of the array substrate 410, thereby reducing the probability of the spacer crushing the array substrate 410.

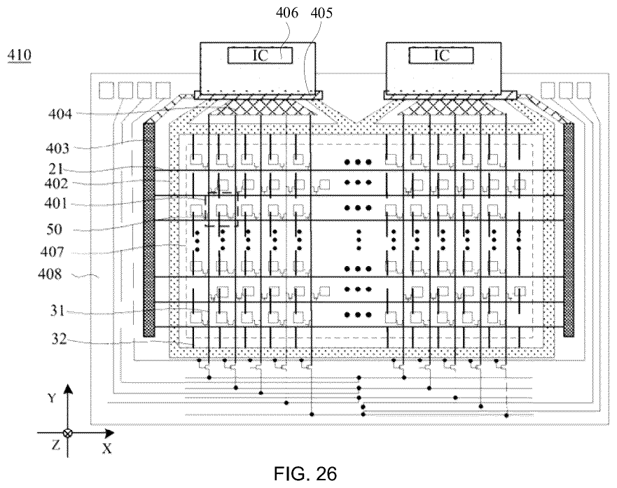

In some embodiments, referring to FIG. 26, the array substrate 410 includes a display area 407 and a peripheral area 408 surrounding the display area 407. The plurality of dimming regions 401 are located in the display area 407. For example, the display area 407 is configured to emit light toward the liquid crystal display panel 100. The array substrate 410 may further include a common voltage signal bus line 402, a gate driving circuit 403, fan-out traces 404, a chip on film 405 and a driver chip 406.

The common voltage signal bus line 402 is located in the peripheral area 408, and the common voltage signal bus line 402 surrounds the display area 407. In the case where the array substrate 410 includes the common voltage signal lines 32, ends of the common voltage signal lines 32 in the first direction Y are connected to the common voltage signal bus line 402. The annular common voltage signal bus line 402 helps to reduce the resistance of the common voltage signal line 32.

The gate driving circuit 403 is located in the peripheral area 408 and is located on at least one side of the display area 407 in the second direction X. For example, as shown in FIG. 26, the gate driving circuit 403 is located on two opposite sides of the display area 407 in the second direction X; that is, the gate driving circuit 403 adopts a double-sided driving method. The gate driving circuit 403 is electrically connected to the plurality of gate lines 21 and configured to transmit a scanning signal to each of the plurality of gate lines 21.

In some other embodiments, the plurality of gate lines 21 may be driven by an integrated chip. That is, the plurality of gate lines 21 may be connected to the integrated chip through the chip on film, and the integrated chip is connected to the plurality of gate lines 21 through the chip on film to transmit scanning signals to the plurality of gate lines 21.

The fan-out traces 404 are located in the peripheral area 408 and on a side of the display area 407 in the first direction Y. The fan-out traces 404 are connected to the plurality of data lines 31 and connected to the chip on film 405. The driver chip 406 is bonded to the chip on film 405. The driver chip 406 is connected to the plurality of data lines 31 through the chip on film 405 and the fan-out traces 404, and configured to transmit data signals to the plurality of data lines 31. That is, the array substrate 410 adopts a chip-on-film (COF) structure.

In some other embodiments, the driver chip 406 may be directly bonded to the peripheral area 408 of the array substrate 410. That is, the array substrate 410 adopts a chip-on-glass (COG, where the driver chip is directly bonded to glass) structure.

The above are merely specific embodiments of the present disclosure, but the protection scope of the present disclosure is not limited thereto, and variations or substitutions that any person skilled in the art may conceive of within the technical scope of the present disclosure should fall within the protection scope of the present disclosure. Therefore, the protection scope of the present disclosure should be subjected to the protection scope of the claims.

1. An array substrate, comprising:
a substrate and a first wiring layer disposed on a side of the substrate, wherein the first wiring layer includes a plurality of gate lines arranged at intervals in a first direction, and at least one gate line extends in a second direction; the first direction intersects with the second direction;
a second wiring layer disposed on a side of the first wiring layer away from the substrate, wherein the second wiring layer includes a plurality of data lines arranged at intervals in the second direction, at least one data line extends in the first direction; an orthographic projection of a gate line of the plurality of gate lines on the substrate intersects with an orthographic projection of a data line of the plurality of data lines on the substrate, two adjacent gate lines of the plurality of gate lines and two adjacent data lines of the plurality of data lines define a dimming region, and the dimming region is configured to switch between a sharing state and a privacy protection state;
a first electrode layer disposed on a side of the second wiring layer away from the substrate, wherein the first electrode layer includes a plurality of first electrodes, and a first electrode is at least partially located in the dimming region; and
a second electrode layer disposed on a side of the first electrode layer away from the substrate, wherein the second electrode layer includes a second electrode, and an orthographic projection of the second electrode on the substrate is at least partially non-overlapping with an orthographic projection of the first electrode on the substrate.

2. The array substrate according to claim 1, wherein
the dimming region is provided with a thin film transistor therein; the thin film transistor is electrically connected to a gate line of the two adjacent gate lines, a data line of the two adjacent data lines and the first electrode, and configured to transmit a data signal from the data line to the first electrode under control of a scanning signal from the gate line; and
the second electrode include a plurality of avoidance openings, and the dimming region is provided with an avoidance opening therein; an orthographic projection of the avoidance opening on the substrate at least partially overlaps with an orthographic projection of the thin film transistor on the substrate.

3. The array substrate according to claim 2, wherein
the thin film transistor includes:
a gate pattern disposed in the first wiring layer and connected to the gate line;
a semiconductor pattern disposed between the first wiring layer and the second wiring layer;
a source pattern disposed in the second wiring layer and connected to the data line; and
a drain pattern disposed in the second wiring layer and spaced apart from the source pattern, wherein an orthographic projection of the drain pattern on the substrate is non-overlapping with the orthographic projection of the first electrode on the substrate; and
an orthographic projection of the gate pattern on the substrate covers orthographic projections of the semiconductor pattern and the source pattern on the substrate, and partially overlaps with the orthographic projection of the drain pattern on the substrate; the orthographic projection of the avoidance opening on the substrate partially overlaps with the orthographic projections of the gate pattern, the semiconductor pattern, and the source pattern on the substrate, and covers the orthographic projection of the drain pattern on the substrate.

4. The array substrate according to claim 3, wherein the avoidance opening includes:
a first opening portion, wherein a shape of a border of the first opening portion is substantially same as a shape of a border of the semiconductor pattern, and an orthographic projection of the first opening portion on the substrate is located within the orthographic projection of the semiconductor pattern on the substrate; and/or
the second electrode layer further includes: a transfer block located in the avoidance opening and having a spacing from a border of the avoidance opening, wherein the transfer block is electrically connected to both the drain pattern and the first electrode.

5. (canceled)

6. The array substrate according to claim 4, wherein the avoidance opening includes:
a second opening portion, wherein a shape of a border of the second opening portion is substantially same as a shape of a border of the transfer block, and the border of the second opening portion surrounds the transfer block; and/or
an orthographic projection of the transfer block on the substrate is non-overlap with orthographic projections of the data line and the gate line on the substrate.

7. (canceled)

8. (canceled)

9. The array substrate according to claim 1, wherein the second electrode includes:
a plurality of third electrode strips arranged at intervals in the second direction and extending in the first direction; and
fourth electrode strips connected to ends of the plurality of third electrode strips, wherein an extension direction of a fourth electrode strip is parallel to an extension direction of the gate line, and an orthographic projection of the fourth electrode strip on the substrate at least partially overlaps with the orthographic projection of the gate line on the substrate.

10. The array substrate according to claim 9, wherein the fourth electrode strip includes at least one protruding portion and straight portions connected to the protruding portion; a dimension of a protruding portion of at least one protruding portion in the first direction is greater than a dimension of a straight portion of the straight portions in the first direction, and a dimension of the protruding portion in the second direction is greater than a dimension of the straight portion in the second direction.

11. The array substrate according to claim 10, wherein the fourth electrode strip includes a plurality of protruding portions and a plurality of straight portions connected to the plurality of protruding portions, and multiple third electrode strips located in a same dimming region include:
a first electrode sub-strip, wherein two ends of the first electrode sub-strip in the first direction are connected to straight portions;
a second electrode sub-strip, wherein in the first direction, an end of the second electrode sub-strip is connected to a straight portion, and another end of the second electrode sub-strip is connected to a protruding portion; and
a third electrode sub-strip, wherein two ends of the third electrode sub-strip in the first direction are connected to protruding portions.

12. (canceled)

13. (canceled)

14. The array substrate according to claim 1, wherein
the first electrode includes a plurality of first electrode strips arranged at intervals in the second direction, and the second electrode includes a plurality of third electrode strips arranged at intervals in the second direction; orthographic projections of the plurality of first electrode strips and the plurality of third electrode strips on the substrate are alternately arranged in the second direction, a first electrode strip and an adjacent third electrode strip is provided with a fourth slit therebetween, and a dimension of the fourth slit in the second direction is less than a dimension of the first electrode strip in the second direction, and/or less than a dimension of the third electrode strip in the second direction.

15. The array substrate according to claim 1, wherein in the dimming region, the first electrode includes:
a plurality of first electrode strips arranged at intervals in the second direction and extending in the first direction; and
a second electrode strip of which two ends are connected to each other, wherein the second electrode strip is connected to two ends of a first electrode strip of the plurality of first electrode strips in the first direction to form a structure in which the second electrode strip encloses the plurality of first electrode strips.

16. The array substrate according to claim 15, wherein the second electrode strip includes:
two fourth electrode sub-strips oppositely arranged in the first direction, wherein an extension direction of a fourth electrode sub-strip is parallel to an extension direction of the gate line, and orthographic projections of the fourth electrode sub-strip and the gate line on the substrate have a first spacing therebetween; and
two fifth electrode sub-strips oppositely arranged in the second direction, wherein an extension direction of a fifth electrode sub-strip is parallel to an extension direction of the data line, and orthographic projections of the fifth electrode sub-strip and the data line on the substrate have a second spacing therebetween; the first spacing is less than or equal to the second spacing.

17. The array substrate according to claim 16, wherein
the fourth electrode sub-strip has a zigzag structure, or the fourth electrode sub-strip has a concave-convex structure; or
the fourth electrode sub-strip has a zigzag structure or a concave-convex structure, a first recess is provided at an edge of the fourth electrode sub-strip proximate to the gate line, and an orthographic projection of the first recess on the substrate and an orthographic projection of the gate line on the substrate have a spacing therebetween.

18. (canceled)

19. The array substrate according to claim 1, wherein the gate line includes at least one light adjustment portion and a connection portion connected to the light adjustment portion, and a width of a light adjustment portion is greater than a width of the connection portion.

20-22. (canceled)

23. The array substrate according to claim 19, wherein the gate line is routed along a broken line and includes a plurality of extension sections sequentially connected in the second direction; and
an extension section includes a plurality of light adjustment portions and a plurality of connection portions that are alternately connected in sequence; and two ends of the extension section are connection portions.

24. The array substrate according to claim 19, wherein a second recess is provided on a side of the first electrode proximate to the light adjustment portion; a shape of the second recess is same as a shape of the light adjustment portion on a side proximate to the first electrode, and a spacing between the second recess and the light adjustment portion is equal to a spacing between the first electrode and the connection portion; and/or
an orthographic projection of the light adjustment portion on the substrate is non-overlapping with an orthographic projection of a thin film transistor on the substrate.

25. (canceled)

26. The array substrate according to claim 1, wherein the gate line includes a plurality of extension sections, and the plurality of extension sections include a plurality of first extension sections and a plurality of second extension sections that are alternately connected; a first extension section and a second extension section that are connected to each other are symmetrically arranged about a first reference line, and an included angle between an extension direction of the first extension section and the second direction or between an extension direction of the second extension direction and the second direction is in a range of 53° to 73°, inclusive; the first reference line is parallel to the first direction; and/or
the data line is routed along a broken line and includes a plurality of third extension sections and a plurality of fourth extension sections that are alternatively arranged and connected in the first direction; a third extension section and a fourth extension section that are connected to each other are symmetrically arranged about a second reference line, and an included angle between an extension direction of the third extension section and the first direction or between an extension direction of the fourth extension direction and the first direction is in a range of 5° to 10°, inclusive; the second reference line is parallel to the second direction.

27. (canceled)

28. The array substrate according to claim 1, wherein the second wiring layer further includes a plurality of common voltage signal lines arranged at intervals in the first direction; and
in the second direction, the plurality of data lines and the plurality of common voltage signal lines are alternately arranged, and a data line and an adjacent common voltage signal line are symmetrically arranged; or
the second wiring layer further includes the plurality of common voltage signal lines arranged at intervals in the first direction; in second direction, the plurality of data lines and the plurality of common voltage signal lines are alternately arranged, and a data line and an adjacent common voltage signal line are symmetrically arranged; a common voltage signal line of the plurality of common voltage signal lines includes a widened portion, the widened portion is electrically connected to the second electrode, and an orthographic projection of the widened portion on the substrate is located in the orthographic projection of the gate line on the substrate.

29. (canceled)

30. The array substrate according to claim 1, wherein the array substrate comprises a display area and a peripheral area surrounding the display area, and the array substrate further comprises:
a common voltage signal bus line located in the peripheral area and surrounding the display area, wherein the array substrate further comprises a common voltage signal line, an end of the common voltage signal line in the first direction is connected to the common voltage signal bus line;
a gate driving circuit located in the peripheral area, wherein the gate driving circuit is disposed on at least one side of the display area in the second direction and electrically connected to the gate line;
a fan-out trace located in the peripheral area, wherein the fan-out trace is disposed on a side of the display area in the first direction and electrically connected to the data line;
a chip on film connected to the fan-out trace; and
a driver chip bonded to the chip on film.

31. A view angel control cell, comprising:
the array substrate according to claim 1, wherein the array substrate includes a plurality of thin film transistors, and each dimming region is provided with a thin film transistor therein; the thin film transistor is configured to control the dimming region of the view angle control cell to switch between a sharing state and a privacy protection state;
an opposite substrate arranged opposite to the array substrate, wherein the opposite substrate and the array substrate define a liquid crystal cell; and
a liquid crystal layer located in the liquid crystal cell, wherein the liquid crystal layer is configured to, under control of a driving circuit of the array substrate, adjust deflection directions of liquid crystal molecules in the liquid crystal layer and located in each dimming region to control light entering each dimming region to be emitted from the liquid crystal layer in the privacy protection state or the sharing state.

32. (canceled)

33. A display apparatus, comprising:
the view angel control cell according to claim 31;
a backlight module disposed on a side of the view angle control cell proximate to the array substrate and configured to output light, whose propagation direction is perpendicular to the view angle control cell, toward a direction approaching the view angel control cell; and
a liquid crystal display panel disposed on a side of the view angel control cell away from the backlight module.

34. (canceled)
